(19) United States
(12) Patent Application Publication
(10) Pub. No.: US 2025/0393218 A1
(43) Pub. Date: Dec. 25, 2025

(54) VOLTAGE-CONTROLLED MAGNETIC ANISOTROPY DEVICE INCLUDING AN ON-CHIP ELECTROMAGNET

(71) Applicant: SANDISK TECHNOLOGIES LLC, ADDISON, TX (US)

(72) Inventors: Michael GROBIS, Campbell, CA (US); Neil ROBERTSON, Palo Alto, CA (US)

(21) Appl. No.: 18/784,034

(22) Filed: Jul. 25, 2024

Related U.S. Application Data
(60) Provisional application No. 63/661,682, filed on Jun. 19, 2024.

(51) Int. Cl. H10B 61/00; G11C 11/16; H10N 50/10

(52) U.S. Cl. CPC H10B 61/00; G11C 11/161; G11C 11/1655; G11C 11/1657; G11C 11/1675; H10N 50/10

(57) ABSTRACT

A magnetoelectric device includes an array of magnetoelectric unit cells located over a substrate, and each of the magnetoelectric unit cells includes a first electrode, a second electrode, and a magnetic tunnel junction located between the first electrode and the second electrode, word lines contacting a respective row of first electrodes of the array of magnetoelectric unit cells, bit lines contacting a respective column of second electrodes of the array of magnetoelectric unit cells, and an electromagnet located over the substrate and configured to apply a magnetic field to the array of magnetoelectric unit cells.

### FIELD

The present disclosure relates generally to the field of magnetic devices and specifically to magnetoelectric random access memory (MeRAM) voltage-controlled magnetic anisotropy devices with an on-chip electromagnet.

### BACKGROUND

Voltage-controlled magnetic anisotropy (VCMA) refers to magnetic anisotropy that increase or decreases with application of an electric field across a magnetic tunnel junction. A VCMA unit cell can be programmed employing the voltage-controlled magnetic anisotropy (VCMA) effect. Thus, the magnetoelectric unit cell can be programmed employing an electrical voltage that is applied in one direction. In other words, a voltage is applied between a selected word line and a selected bit line, and the magnetoelectric unit cell can be toggled back and forth between the parallel and anti-parallel states by pulsing a voltage in one direction (e.g., in forward bias mode). In one embodiment, a very small current may flow between the free layer and the reference layer of the magnetic tunnel junction during the writing step. However, the current is typically so small that spin-transfer torque (STT) effects can be ignored.

### SUMMARY

According to an embodiment of the present disclosure, a magnetoelectric device includes an array of magnetoelectric unit cells located over a substrate, and each of the magnetoelectric unit cells includes a first electrode, a second electrode, and a magnetic tunnel junction located between the first electrode and the second electrode, word lines contacting a respective row of first electrodes of the array of magnetoelectric unit cells, bit lines contacting a respective column of second electrodes of the array of magnetoelectric unit cells, and an electromagnet located over the substrate and configured to apply a magnetic field to the array of magnetoelectric unit cells.

### BRIEF DESCRIPTION OF THE DRAWINGS

FIG. 1 is a schematic diagram of a device including an array of magnetoelectric unit cells according to an embodiment of the present disclosure.

FIG. 2A is a vertical cross-sectional view of a first exemplary magnetoelectric device including an array of magnetoelectric unit cells according to an embodiment of the present disclosure.

FIG. 2B is a top-down view of the first exemplary magnetoelectric device of FIG. 2A.

FIG. 3A is a vertical cross-sectional view of a second exemplary magnetoelectric device including four arrays of magnetoelectric unit cells according to an embodiment of the present disclosure.

FIG. 3B is a top-down view of the second exemplary magnetoelectric device of FIG. 3A during a programming operation on a first array and a second array.

FIG. 3C is a top-down view of the second exemplary magnetoelectric device of FIG. 3A during a programming operation on a third array and a fourth array.

FIG. 4A is a vertical cross-sectional view of a third exemplary magnetoelectric device including four arrays of magnetoelectric unit cells according to an embodiment of the present disclosure.

FIG. 4B is a top-down view of the third exemplary magnetoelectric device of FIG. 4A.

FIG. 5 illustrates a first configuration of an exemplary magnetoelectric unit cell according to a embodiment of the present disclosure.

FIG. 6 illustrates a second configuration of the exemplary magnetoelectric unit cell according to an embodiment of the present disclosure.

FIG. 7 illustrates a third configuration of the exemplary magnetoelectric unit cell according to an embodiment of the present disclosure.

FIG. 8 illustrates a fourth configuration of the exemplary magnetoelectric unit cell according to an embodiment of the present disclosure.

FIG. 9A illustrates an exemplary programming pulse pattern for switching a magnetization state of a free layer from a parallel state to an antiparallel state according to an embodiment of the present disclosure.

FIG. 9B illustrates a second exemplary programming pulse pattern for switching a magnetization state of a free layer from an antiparallel state to a parallel state according to an embodiment of the present disclosure.

### DETAILED DESCRIPTION

As discussed above, the present disclosure is directed to magnetoelectric random access memory (MeRAM) voltage-controlled magnetic anisotropy devices including an on-chip electromagnet, the various aspects of which are described below.

The drawings are not drawn to scale. Multiple instances of an element may be duplicated where a single instance of the element is illustrated, unless absence of duplication of elements is expressly described or clearly indicated otherwise. Same reference numerals refer to the same element or to a similar element. Elements having the same reference numerals are presumed to have the same material composition unless expressly stated otherwise. Ordinals such as “first,” “second,” and “third” are employed merely to identify similar elements, and different ordinals may be employed across the specification and the claims of the instant disclosure. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, an “in-process” structure or a “transient” structure refers to a structure that is subsequently modified.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, and/or may have one or more layer thereupon, thereabove, and/or therebelow.

As used herein, a “layer stack” refers to a stack of layers. As used herein, a “line” refers to a layer that has a predominant direction of extension, i.e., having a direction along which the layer extends the most.

The expansion of artificial intelligence (AI) applications is straining the capabilities of conventional processing units to keep pace with the soaring demands for size, power, and performance. Particularly, large language models require immense storage for trillions of weights and trillions of multiplication operations per output token. Traditional AI computation largely relies on graphics processing units (GPUs) coupled with integrated DRAM for weight caching. While effective, this method proves highly costly in terms of both power consumption and financial expense.

To address these challenges, analog compute-in-memory (CIM) solutions for AI computation using resistance-based technologies such as resistive RAM (ReRAM), phase change memory (PCM), and spin transfer torque magnetoresistive RAM (STT-MRAM) have been proposed. However, these technologies have fallen short in performance for AI computation compared to conventional logic device computing due to their inefficiencies in programmability and energy consumption.

According to an aspect of the present disclosure, a CIM solution for AI computation is provided, in which vector-matrix multiplication (VMM) is performed using voltage-controlled-magnetic-anisotropy (VCMA) MeRAM with on-chip electromagnet which generates (e.g., internally generates) magnetic fields for programming the VCMA MeRAM unit cells. In other words, no external magnetic field generated outside the magnetoelectric device chip is needed.

Specifically, embodiments of the present disclosure provide a magnetoelectric device that incorporates an on-chip electromagnet which generates a magnetic field to facilitate reprogramming of VCMA MeRAM cells during operation of the device. The magnetoelectric device of the embodiments of the present disclosure includes a two-dimensional array of magnetoelectric unit cells, each comprising a magnetic tunnel junction between between two electrodes, and an electromagnet which generates the magnetic field in response to an application of a current to the electromagnet. The electromagnet may comprise an electrically conductive wire which either surrounds the magnetoelectric unit cells themselves, or which is located above or below the magnetoelectric unit cells and surrounds the vertical projection of the area occupied by the magnetoelectric unit cells. The electromagnet wire is located over the same MeRAM chip substrate and the magnetoelectric unit cells.

The on-chip electromagnet improves the power efficiency and reduces the cost of VCMA MeRAM arrays. The VCMA MeRAM arrays may be used for VMM calculations for AI operation. The various embodiments of the present disclosure are now described in detail with reference to accompanying drawings.

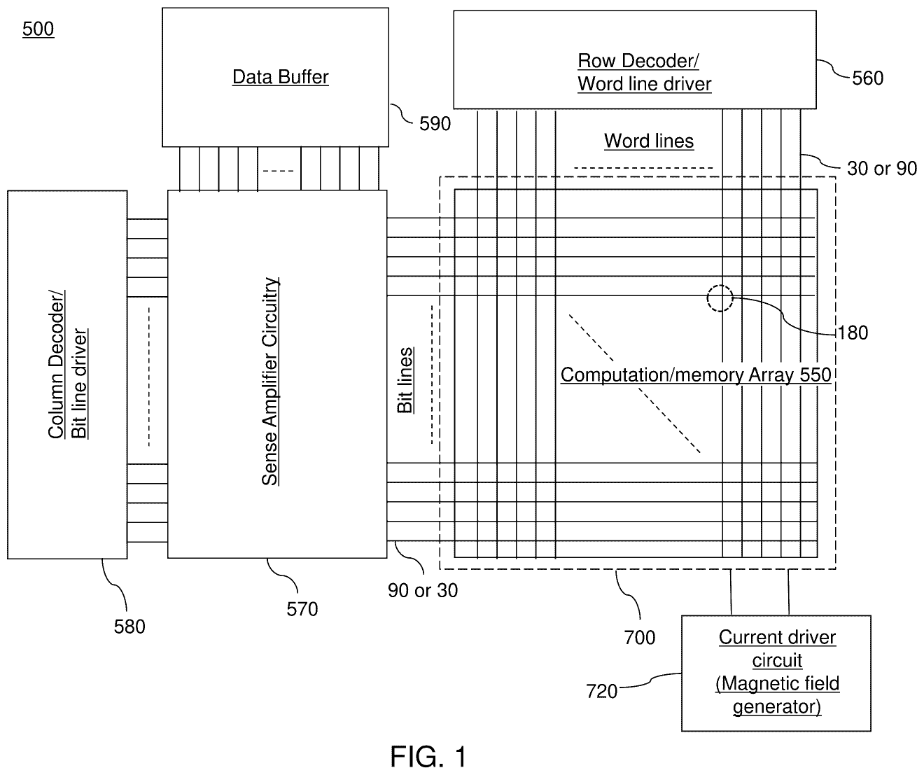

Referring to FIG. 1, a schematic diagram is shown for a magnetoelectric device 500 including unit cells 180. As used herein, a magnetoelectric device refers to a device, such as the VCMA MeRAM device, employing magnetoelectric effects, i.e., coupling between magnetic properties and electrical properties. As used herein, a magnetoelectric unit cell refers to any unit device structure that may be employed as a computation unit (i.e., a computation cell) or as a memory unit (i.e., a memory cell). A unit cell may be a computation cell that may be employed as a compute-in-memory (CIM) processing cell (e.g., artificial intelligence-type computation cell used for VMM calculations), a memory cell that may be employed to store a data bit, or a hybrid cell that may be employed as a computation cell or as a memory cell interchangeably.

The unit cells 180 may have any configuration described herein, or any alternative configuration provided that a magnetic tunnel junction is present therein. The magnetoelectric device 500 includes an array of unit cells 180, which may be configured as a two-dimensional array or as a three-dimensional array. In some embodiments, the magnetoelectric device 500 may be in a random access memory (RAM) configuration. As used herein, a “random access memory” (RAM) refers to a device containing unit cells that allow random access, e.g., access to any selected unit cell upon a command for reading the contents of the selected unit cell.

The magnetoelectric device 500 of an embodiment of the present disclosure includes a computation/memory array 550 containing an array of unit cells 180 located at the intersection of the respective word lines (which may comprise first electrically conductive lines 30 as illustrated or as second electrically conductive lines 90 in an alternate configuration) and bit lines (which may comprise second electrically conductive lines 90 as illustrated or as first electrically conductive lines 30 in an alternate configuration). In case the second electrically conductive lines 90 overlie the first electrically conductive lines 30 in a physical magnetoelectric device, the first electrically conductive lines 30 may be referred to as lower electrically conductive lines, and the second electrically conductive lines 90 may be referred to as upper electrically conductive lines. Each of the unit cells 180 can be a two terminal unit cell including a respective first electrode (which is one of a bottom electrode 32 and a top electrode 92) and a respective second electrode (which is the other of the bottom electrode 32 and the top electrode 92). In one embodiment, the first electrodes (32 or 92) can be connected to the word lines (30 or 90), and the second electrodes (92 or 32) can be connected to the bit lines (90 or 30).

The magnetoelectric device 500 may also contain a row decoder/word line driver 560 connected to the word lines (30 or 90), a sense circuitry 570 (e.g., a sense amplifier and other bit line control circuitry) connected to the bit lines (90 or 30), a column decoder/bit line driver 580 connected to the sense circuitry 570, and a data buffer 590 connected to the sense circuitry 570. Multiple instances of the unit cells 180 are provided in an array configuration that forms the magnetoelectric device 500. It should be noted that the location and interconnection of elements are schematic and the elements may be arranged in a different configuration. Further, a magnetoelectric unit cell 180 may be manufactured as a discrete device, i.e., a single isolated device.

Each unit cell 180 includes a magnetic tunnel junction having at least two different resistive states depending on the alignment of magnetizations of different magnetic material layers. The magnetic tunnel junction is provided between a first electrode and a second electrode within each unit cell 180 In the first and second embodiments, the magnetoelectric device 500 comprises the VCMA magnetoelectric RAM (MeRAM) device, and each unit cell 180 can be a voltage-controlled magnetic anisotropy (VCMA) magnetoelectric unit cell in which the magnetization of the free layer can be controlled by an applied voltage. The magnetization may be programmed non-deterministically by timing the duration of a unipolar voltage pulse that induces precession in the free layer in the presence of magnetic field that is configured to be perpendicular to the axis of the magnetization, and stopping the voltage pulse when the desired magnetization direction is achieved during the precession.

According to an aspect of the present disclosure, an on-chip, embedded electromagnet 700 can be provided. The embedded electromagnet 700 is configured to provide a magnetic field to the array of unit cells 180. The magnetic field is parallel or substantially parallel to the axis of the magnetic tunnel junctions of the unit cells 180. The axis extends in a direction between the free layer and the reference layer of the magnetic tunnel junctions of the unit cells 180. For ease of explanation, if the unit cells 180 are located over a major surface of a substrate, then the plane of the major surface is referred to as a horizontal plane, and the axis direction (i.e., the free layer, tunnel barrier layer and reference layer stack direction) is referred to as a vertical direction which is perpendicular to the horizontal plane. Thus, the magnetic field generated by the electromagnet may be vertical or substantially vertical. The electromagnet is embedded within dielectric material layers of the MeRAM chip or die that also embed the array of unit cells 180. Generally, the direction of the magnetic field within any volume within the array of unit cells 180 does not deviate from the vertical direction by more than 45 degrees, and preferably does not deviate from the vertical direction by more than 30 degrees. A current driver circuit 720 is also provided, which is configured to flow electric current through conductive wires (not shown in FIG. 1) of the embedded electromagnet 700 such that the magnetic field is applied to the array of unit cells 180. The current driver circuit 720 is also referred to as a magnetic field generator.

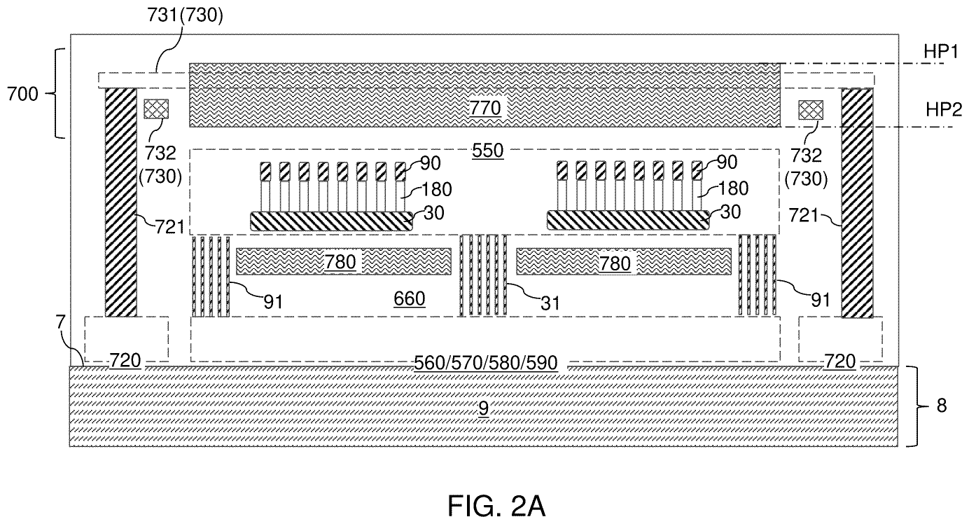

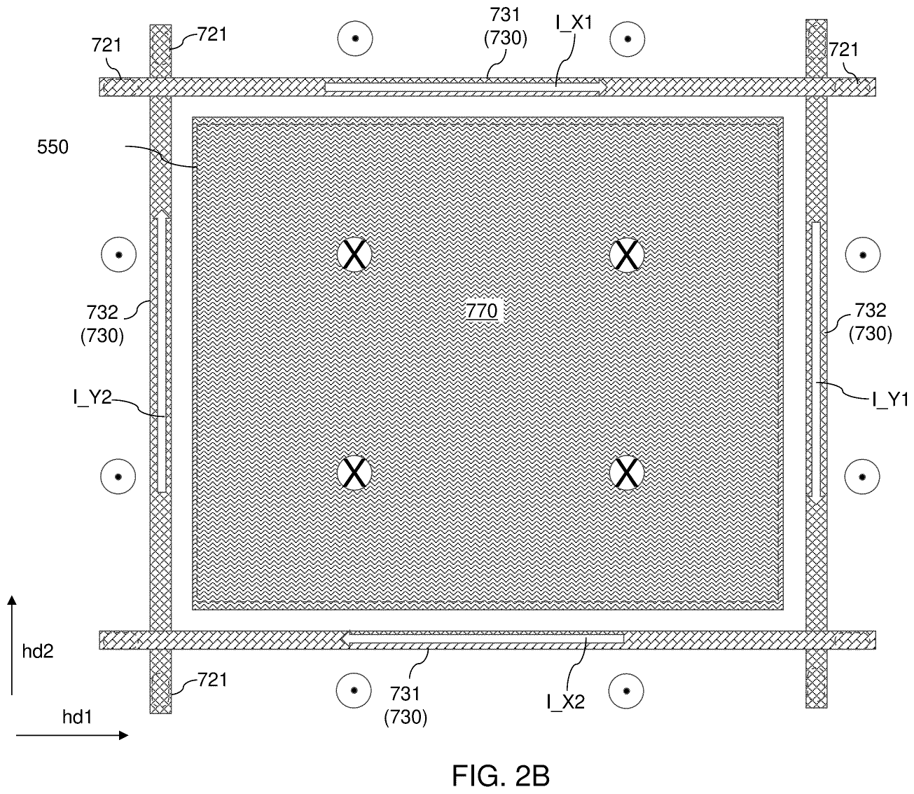

Referring to FIGS. 2A and 2B, a first exemplary magnetoelectric device including an array of magnetoelectric unit cells 180 and an embedded electromagnet according to an embodiment of the present disclosure is illustrated. The first exemplary magnetoelectric device may comprise a substrate 8 having a major (e.g., upper) surface 7. The substrate 8 may comprise a semiconductor, insulating or conductive substrate. For example, the substrate 8 may comprise a semiconductor substrate including a semiconductor material layer 9 at least in an upper portion thereof. For example, the semiconductor substrate 8 may comprise a commercially-available silicon wafer such as a bulk single crystalline semiconductor wafer or a silicon-on-insulator wafer, and the semiconductor material layer 9 may comprise a doped well in the upper portion of the wafer or an epitaxial semiconductor (e.g., silicon) layer deposited on the substrate.

The row decoder/word line driver 560, the sense circuitry 570, the column decoder/bit line driver 580, and the data buffer 590 described with reference to FIG. 1 may be formed over the top surface 7 of the semiconductor material layer 9. Further, a current driver circuit 720 for supplying electric current to electrically conductive lines (e.g., which form a spiral or circular wire) 730 within the embedded electromagnet 700 can be provided over the top surface of the semiconductor material layer 9. Each of the row decoder/word line driver 560, the sense circuitry 570, the column decoder/bit line driver 580, the data buffer 590, and the current driver circuit 720 may comprise circuits containing complementary metal-oxide-semiconductor (CMOS) devices, other transistors, resistors, capacitors, etc., Dielectric material layers 660 can be formed above the row decoder/word line driver 560, the sense circuitry 570, the column decoder/bit line driver 580, the data buffer 590, and the current driver circuit 720. The dielectric material layer 660 may comprise any interlayer dielectric (ILD) material known in the art, such as undoped silicate glass (i.e., silicon oxide), a doped silicate glass, porous or non-porous organosilicate glass, etc.

Various metal interconnect structures (31, 91, 721) may be formed within the dielectric material layers 660. The various metal interconnect structures (31, 91, 721) may comprise conductive vias that are configured to provide electrical paths between the various circuits (560, 570, 580, 590, 720) on the substrate 8 and the various electrical nodes of a two-dimensional array of magnetoelectric unit cells 180 and the embedded electromagnet 700. For example, the various metal interconnect structures (31, 91, 721) may comprise first metal interconnect structures 31 configured to provide electrically conductive paths between the row decoder/word line driver 560 and the first electrically conductive lines (e.g., word lines) 30, second metal interconnect structures 91 configured to provide electrically conductive paths between the sense circuitry 570 and the second electrically conductive lines (e.g., bit lines) 90, and third metal interconnect structures 721 (which are also referred to as field-generation metal interconnect structures) configured to provide electrically conductive paths between the current driver circuit 720 and the conductive lines 730 of the embedded electromagnet 700.

A computation/memory array 550 is located over the various circuits (560, 570, 580, 590, 720), and may be embedded within the dielectric material layers 660. An optional magnetic field generation plate 770 may be provided over the computation/memory array 550. An optional soft magnetic material plate 780 may be provided below the computation/memory array 550. The optional magnetic field generation plate 770 and/or the optional soft magnetic material plate 780 may also be embedded within the dielectric material layers 660.

The computation/memory array 550 comprises a two-dimensional array of magnetoelectric unit cells 180, first electrically conductive lines (e.g., word lines) 30, and second electrically conductive lines (e.g., bit lines) 90. Each of the magnetoelectric unit cells 180 comprises a first electrode (32 or 92), a second electrode (92 or 32), and a magnetic tunnel junction located between the first electrode (32 or 92) and the second electrode (92 or 32). As discussed above, the first electrically conductive lines 30 may be word lines or bit lines, and the second electrically conductive lines 90 may be bit lines or word lines. If the first electrically conductive lines 30 comprise word lines, the second electrically conductive lines 90 comprise bit lines, and vice versa. Generally, the word lines (30 or 90) contact a respective row of first electrodes (32 or 92) of the two-dimensional array of magnetoelectric unit cells 180, and the bit lines (90 or 30) contact a respective column of second electrodes (92 or 32) of the two-dimensional array of magnetoelectric unit cells 180. The row decoder/word line driver 560 is connected to the word lines (30 or 90), for example, through the first metal interconnect structures 31 or through the second metal interconnect structures 91. The sense circuitry 570 (e.g., a sense amplifier and other bit line control circuitry) is connected to the bit lines (90 or 30), for example, through the second metal interconnect structures 91 or through the first metal interconnect structures 31.

The magnetic field generation plate 770, if present, comprises a paramagnetic material. Exemplary paramagnetic materials that may be employed for the magnetic field generation plate 770 include, but are limited to, aluminum, platinum, molybdenum, tantalum or tungsten, or other paramagnetic metals or metal alloys.

The soft magnetic material plate 780 comprises a soft magnetic material. As used herein, a “soft magnetic material” refers to a material having an intrinsic coercivity less than 1,000 Amperes per meter. Exemplary soft magnetic materials that may be employed for the soft magnetic material plate 780 include, but are limited to, silicon steel, nickel-iron alloys, cobalt-iron alloys, amorphous metal alloys, and nanocrystalline alloys. Silicon steel contains between 2 and 4 weight percent silicon. Nickel-iron alloys, such as permalloys, typically comprise about 30 to 80 weight percent nickel and 20 to 70 weight percent iron. Amorphous metal alloys typically comprise a mixture of iron, silicon, boron, and optionally cobalt and provide very low coercivity. Nanocrystalline alloys can be formed by controlled crystallization of amorphous metal precursors and typically include iron with small amounts of niobium, copper, silicon, and/or boron.

Each of the magnetic field generation plate 770 and the soft magnetic material plate 780 can be formed by deposition and patterning of a respective layer. In one embodiment, the shape and the size of the magnetic field generation plate 770 can be selected such that the entire area of the two-dimensional array of magnetoelectric unit cells 180 has an areal overlap with the magnetic field generation plate 770. In one embodiment, the shape and the size of the soft magnetic material plate 780 can be selected such that the entire area of the two-dimensional array of magnetoelectric unit cells 180 has an areal overlap with the soft magnetic material plate 780.

In one embodiment, the magnetic field generation plate 770 overlies the two-dimensional array of magnetoelectric unit cells 180, the first electrically conductive lines 30, and the second electrically conductive lines 90. In one embodiment, the soft magnetic material plate 780 underlies the two-dimensional array of magnetoelectric unit cells 180, the first electrically conductive lines 30, and the second electrically conductive lines 90.

Generally, at least one conductive line (e.g., conductive wire) 730 may be arranged around the periphery of the magnetic field generation plate 770 (if present) to form the electromagnet 700. The at least one conductive line 730 may comprise a coil which surrounds the magnetic field generation plate 770. A magnetic field is generated around the at least one conductive line 730 once the current driver circuit 720 applies an electric current through the at least one conductive line 730. The vector representing the magnitude and the direction of the magnetic field at any point is the magnetic flux density B. The magnetic flux density B is oriented generally along the vertical direction within the magnetic field generation plate 770, within the volumes of the two-dimensional array of magnetoelectric unit cells 180, and within the soft magnetic material plate 780. The magnetic field generation plate 770 captures the magnetic flux (i.e., the surface integral of the magnetic flux density B within a surface bounded by the sidewalls of the magnetic field generation plate 770) therein such that a higher fraction of the magnetic flux is directed toward the two-dimensional array of magnetoelectric unit cells 180 relative to a configuration in which the magnetic field generation plate 770 is not present. However, if the magnetic field generation plate 770 is omitted, then the least one conductive line 730 may be coiled around the array of magnetoelectric unit cells 180 or may be located above, below, or both above and below the array of magnetoelectric unit cells 180 to generate the magnetic field. Likewise, the soft magnetic material plate 780 captures the magnetic flux (i.e., the surface integral of the magnetic flux density B within a surface bounded by the sidewalls of the soft magnetic material plate 780) therein such that a higher fraction of the magnetic flux remains within the volume of the two-dimensional array of magnetoelectric unit cells 180 relative to a configuration in which the soft magnetic material plate 780 is not present.

In one embodiment, the at least one conductive line 730 comprises a plurality of conductive lines 730 laterally extending along different directions to form a coil of the electromagnet 700. In one embodiment shown in FIG. 2B, the current driver circuit 720 is configured to flow the electric current through each of the plurality of conductive lines 730 along a respective electric current direction such that each of the electric current directions points clockwise in a top-down view, or each of the electric current directions points counterclockwise in the top-down view.

In one embodiment shown in FIG. 2B, the magnetic field generation plate 770 has a pair of first straight sidewalls that laterally extend along a first horizontal direction hd1 and a pair of second straight sidewalls that laterally extend along a second horizontal direction hd2 perpendicular to the first horizontal direction hd1. The plurality of conductive lines 730 comprise a pair of first conductive lines 731 that laterally extend along the first horizontal direction hd1 and a pair of second conductive lines 732 that laterally extend along the second horizontal direction hd2. In one embodiment, the current driver circuit 720 is configured to flow electric current through the pair of first conductive lines 731 in opposite directions, and is configured to flow electric current through the pair of second conductive lines 732 in opposite directions. As discussed above, each of the electric current directions flows clockwise in a top-down view, or each of the electric current directions flows counterclockwise in the top-down view so that the magnetic flux density B generated by each electric current flow add up constructively along an upward vertical direction or along a downward vertical direction.

In the embodiment of FIG. 2B, the electric current I_X1 through the first conductive line 731 located in an upper portion within the area shown in the top-down view of FIG. 2B can flow from left to right, the electric current I_X2 through the first conductive line 731 located in a lower portion within the area shown in the top-down view of FIG. 2B can flow from right to left, the electric current I_X3 through the second conductive line 732 located in a left portion within the area shown in the top-down view of FIG. 2B can flow from bottom to top, and the electric current I_X4 through the second conductive line 732 located in a right portion within the area shown in the top-down view of FIG. 2B can flow from top to bottom. In this case, each electric current flow generates a respective magnetic flux density B that points downward within the entire volume of the magnetic field generation plate 770, the two-dimensional array of magnetoelectric unit cells 180, and the soft magnetic material plate 780. The magnetic flux densities B from the four conductive lines (731, 732) generate the magnetic flux density B within the magnetic field generation plate 770, within the volumes of the two-dimensional array of magnetoelectric unit cells 180, and within the soft magnetic material plate 780.

In one embodiment, the area of the pair of second conductive lines 732 may have an areal overlap with the pair of first conductive lines 731 in a plan view (such as a top-down view), and the pair second conductive lines 732 is vertically offset relative to the pair of first conductive lines 731. Alternatively, the area of the pair of second conductive lines 732 does not have any areal overlap with the pair of first conductive lines 731 in the plan view, and the pair second conductive lines 732 may be formed at the same level as the pair of first conductive lines 731. In one embodiment, the plurality of conductive lines 730 are not in direct contact with each other.

In one embodiment, each of the plurality of conductive lines 730 is laterally offset from a respective sidewall of the magnetic field generation plate 770 by a respective uniform spacing. In one embodiment, the current driver circuit 720 is located on the substrate 8; and the two-dimensional array of magnetoelectric unit cells 180 is located over the current driver circuit 720. In one embodiment, each of the plurality of conductive lines 730 comprises: a respective first end portion that is electrically connected to a respective first metal interconnect structure 721 that provides an electrical connection to a respective first node of the current driver circuit 720; and a respective second end portion that is electrically connected to a respective second metal interconnect structure 721 that provides an electrical connection to a respective second node of the current driver circuit 720.

In one embodiment shown in FIG. 2A, a topmost surface of the at least one conductive line 730 is located below a first horizontal plane HP1 including a top surface of the magnetic field generation plate 770; and a bottommost surface of the at least one conductive line 730 is located above a second horizontal plane HP2 including a bottom surface of the magnetic field generation plate 770.

In one embodiment shown in FIG. 2A, the magnetic field generation plate 770 overlies the word lines (30 or 90), the two-dimensional array of magnetoelectric unit cells 180, and the bit lines (90 or 30), and has an areal overlap with the entirety of the two-dimensional array of magnetoelectric unit cells 180 in a plan view such as a top-down view. In one embodiment, the soft magnetic material plate 780 underlies the word lines (30 or 90), the two-dimensional array of magnetoelectric unit cells 180, and the bit lines (90 or 30), and has an areal overlap with the entirety of the two-dimensional array of magnetoelectric unit cells 180 in a plan view such as a top-down view.

Generally, the word line driver circuit 560 and the bit line driver circuit 580 are configured to provide a unipolar voltage pulse across a selected magnetoelectric unit cell 180 within the two-dimensional array of magnetoelectric unit cells 180. The unipolar voltage pulse induces precession of a magnetization direction in a free layer of the selective magnetoelectric unit cell 180 while a vertical magnetic field generated by the electromagnet 700 is present within the two-dimensional array of magnetoelectric unit cells 180 and in the magnetic field generation plate 770.

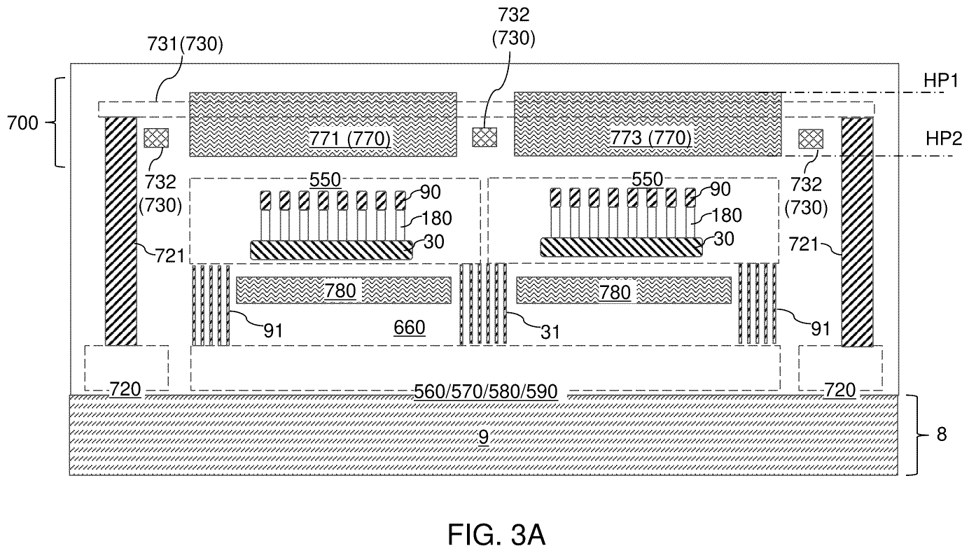

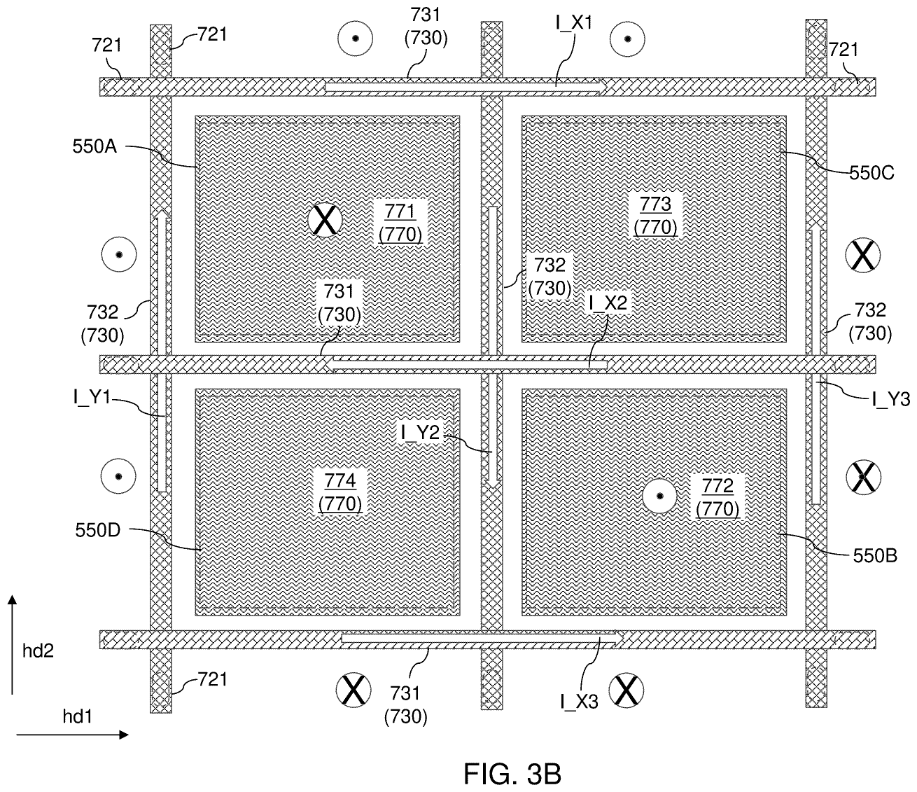

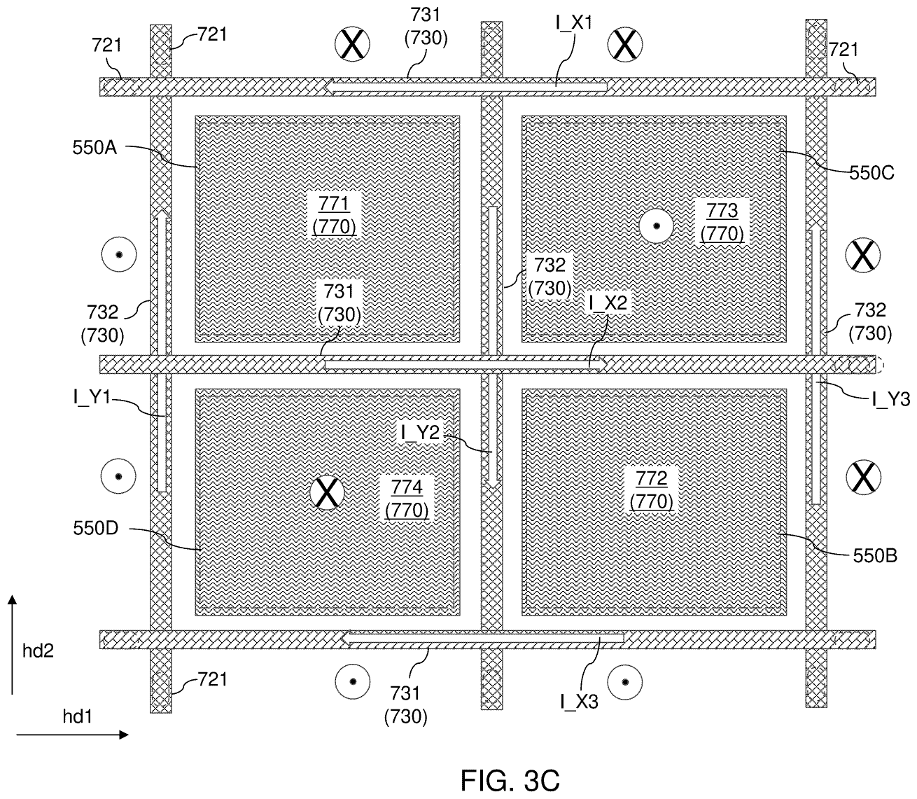

Referring to FIGS. 3A-3C, a second exemplary magnetoelectric device including four arrays (550A, 550B, 550C, 550D) of magnetoelectric unit cells 180 is illustrated. Each array (550A, 550B, 550C, 550D) of magnetoelectric unit cells 180 can be provided with a respective set of word lines (30 or 90) contacting a respective row of first electrodes (32 or 92) of the respective two-dimensional array of magnetoelectric unit cells 180, and a respective set of bit lines (90 or 30) contacting a respective column of second electrodes (92 or 32) of the respective two-dimensional array of magnetoelectric unit cells 180. An optional magnetic field generation plate 770 may overlie each two-dimensional array (550A, 550B, 550C, 550D) of magnetoelectric unit cells 180, and an optional soft magnetic material plate 780 may underlie each two-dimensional array (550A, 550B, 550C, 550D) of magnetoelectric unit cells 180. Generally, the second exemplary magnetoelectric device may be the same as plurality of laterally adjacent first exemplary magnetoelectric devices described with reference to FIGS. 2A and 2B with a modification in the configurations of the conductive lines 730.

In the illustrated example of FIGS. 3A-3C, the magnetic field generation plate 770 may comprise a first-array magnetic field generation plate 771 that overlies a first array 550A of magnetoelectric unit cells 180, a second-array magnetic field generation plate 772 that overlies a second array 550B of magnetoelectric unit cells 180, a third-array magnetic field generation plate 773 that overlies a third array 550C of magnetoelectric unit cells 180, and a fourth-array magnetic field generation plate 773 that overlies a fourth array 550D of magnetoelectric unit cells 180. The arrays of magnetoelectric unit cells 180 may be arranged as a rectangular array, the conductive lines 730 may be arranged in a grid pattern such that a conductive line 730 is provided proximal to each sidewall of the magnetic field generation plates 770.

Generally, for each array of magnetoelectric unit cells 180, at least one conductive line 730 laterally extending along a respective sidewall of a respective overlying magnetic field generation plate 770 is provided. A current driver circuit 720 is configured to provide an electric current through the conductive lines 730 during a programming operation for the array of magnetoelectric unit cells 180. In the configuration illustrated in FIGS. 3A-3C, simultaneous programming is possible for less than all arrays of magnetoelectric unit cells 180.

Specifically, simultaneous programming of magnetoresistive unit cells 180 in the first array 550A of magnetoelectric unit cells 180 (which underlies the first-array magnetic field generation plate 771) and in the second array 550C of magnetoelectric unit cells 180 (which underlies the second-array magnetic field generation plate 772) while the electric currents (I_X1, I_X2, I_X3, I_Y1, I_Y2, I_Y3) flow in the current flow directions illustrated in FIG. 3B. During the current flow configuration illustrated in FIG. 3B, contributions to the magnetic flux density B from the various conductive lines 730 in the third array 550C of magnetoelectric unit cells 180 and the fourth array 550D of magnetoelectric unit cells 180 cancel out, and the magnitude of the magnetic flux density B from the various conductive lines 730 in the third array 550C of magnetoelectric unit cells 180 and the fourth array 550D of magnetoelectric unit cells 180 is negligible. In the top-down view of FIG. 3B, the magnetic flux density B points downward in the first array 550A of magnetoelectric unit cells 180, and points upward in the second array 550B of magnetoelectric unit cells 180.

Likewise, simultaneous programming of magnetoresistive unit cells 180 in the third array 550C of magnetoelectric unit cells 180 (which underlies the third-array magnetic field generation plate 773) and in the fourth array 550D of magnetoelectric unit cells 180 (which underlies the fourth-array magnetic field generation plate 774) while the electric currents (I_X1, I_X2, I_X3, I_Y1, I_Y2, I_Y3) flow in the current flow directions illustrated in FIG. 3C. During the current flow configuration illustrated in FIG. 3C, contributions to the magnetic flux density B from the various conductive lines 730 in the first array 550A of magnetoelectric unit cells 180 and the second array 550B of magnetoelectric unit cells 180 cancel out, and the magnitude of the magnetic flux density B from the various conductive lines 730 in the first array 550A of magnetoelectric unit cells 180 and the second array 550B of magnetoelectric unit cells 180 is negligible. In the top-down view of FIG. 3B, the magnetic flux density B points upward in the third array 550C of magnetoelectric unit cells 180, and points upward in the fourth array 550D of magnetoelectric unit cells 180. Different combinations of electric current directions can result in changes in the magnetization direction and different arrays of magnetoelectric unit cells 180 under non-zero magnetic flux density B.

For each array of magnetoelectric unit cells 180, at least one conductive line 730 laterally surrounding and proximal to the array of magnetoelectric unit cells 180 may comprise a respective plurality of conductive lines 730 laterally extending along different directions. In one embodiment, the current driver circuit 720 may be configured to flow the electric current through each of the plurality of conductive lines 730 along a respective electric current direction such that each of the electric current directions flows clockwise in a top-down view, or each of the electric current directions flows counterclockwise in the top-down view.

In one embodiment, each magnetic field generation plate 770 may have a pair of first straight sidewalls that laterally extend along a first horizontal direction hd1 and a pair of second straight sidewalls that laterally extend along a second horizontal direction hd2, and the plurality of conductive lines 730 laterally surrounding the magnetic field generation plate 770 may comprise a pair of first conductive lines 731 that laterally extend along the first horizontal direction hd1 and a pair of second conductive lines 732 that laterally extend along the second horizontal direction hd2. In one embodiment, the current driver circuit 720 is configured to flow electric current through the pair of first conductive lines 731 in opposite directions, and is configured to flow electric current through the pair of second conductive lines 732 in opposite directions. As discussed above, each of the electric current directions flows clockwise in a top-down view, or each of the electric current directions flows counterclockwise in the top-down view so that the magnetic flux density B generated by each electric current flow add up constructively along an upward vertical direction or along a downward vertical direction.

Generally, for each two-dimensional array 550A of magnetoelectric unit cells 180 underlying a magnetic field generation plate 771, an additional two-dimensional array 550B of magnetoelectric unit cells 180 underlying an additional magnetic field generation plate 772 can be provided as a neighboring two-dimensional array of magnetoresistive unit cells 180. At least one conductive line 730 that laterally surrounds the magnetic field generation plate 771 may be located between the magnetic field generation plate 771 and the additional magnetic field generation plate 772, and may be configured to generate an upward-pointing magnetic field in one of the magnetic field generation plate 771 and the additional magnetic field generation plate 772, and to generate a downward-pointing magnetic field in the magnetic field generation plate 771 and the additional magnetic field generation plate 772 under Ampere's law. The at least one conductive line 730 is laterally offset from a proximal sidewall of the magnetic field generation plate 771 by a first uniform lateral offset distance, and is laterally offset from a proximal sidewall of the additional magnetic field generation plate 772 by a second uniform lateral offset distance.

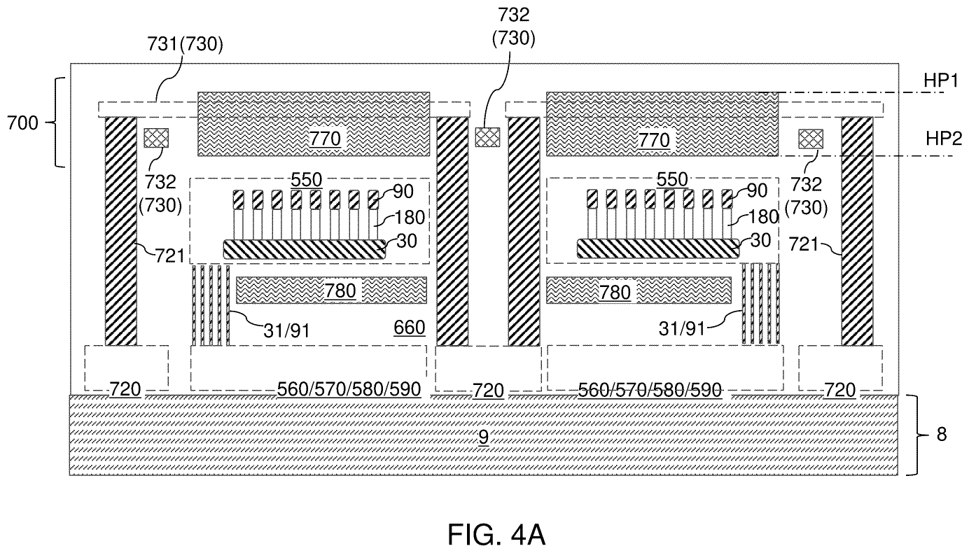

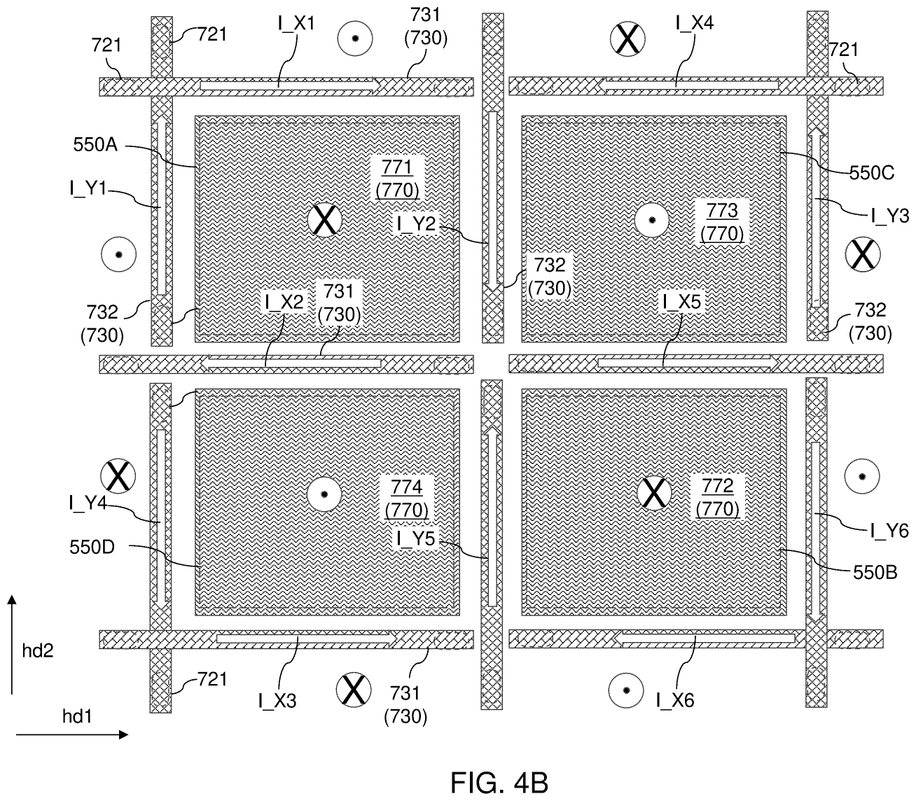

Referring to FIGS. 4A and 4B, a third exemplary magnetoelectric device including four arrays (550A, 550B, 550C, 550D) of magnetoelectric unit cells is illustrated. In the third exemplary magnetoelectric device, the gaps between the two-dimensional arrays of magnetic field generation plates 770 have a grid pattern with cross-point areas (i.e., intersection areas at which gaps laterally extending along the first horizontal direction hd1 and gaps laterally extending along the second horizontal direction hd2 intersect). The length of each conductive line 730 can be selected such that each conductive line 730 does not extend along a respective lengthwise direction past any cross-point area of the gaps. In this case, the primary effect the magnetic flux density B generated by each conductive line 730 is limited to the area of a respective neighboring pair of magnetic field generation plates 770, and thus, to the area of a respective neighboring pair of two-dimensional arrays (550A, 550B, 550C, 550D) of magnetoelectric unit cells 180. In this case, the direction of the electric current (I_X1, I_X2, I_X3, I_X4, I_X5, I_X6, I_Y1, I_Y2, I_Y3, I_Y4, I_Y5, I_Y6) in each of the conductive lines 730 may be independently controlled, and the combined magnetic flux density B is provided within each of the magnetic field generation plates 770, within each of the two-dimensional arrays (550A, 550B, 550C, 550D) of magnetoelectric unit cells 180, and within each of the second soft magnetization material plates 780. Thus, selected magnetoelectric unit cells 180 may be programmed in each of the two-dimensional arrays (550A, 550B, 550C, 550D) of magnetoelectric unit cells 180 simultaneously.

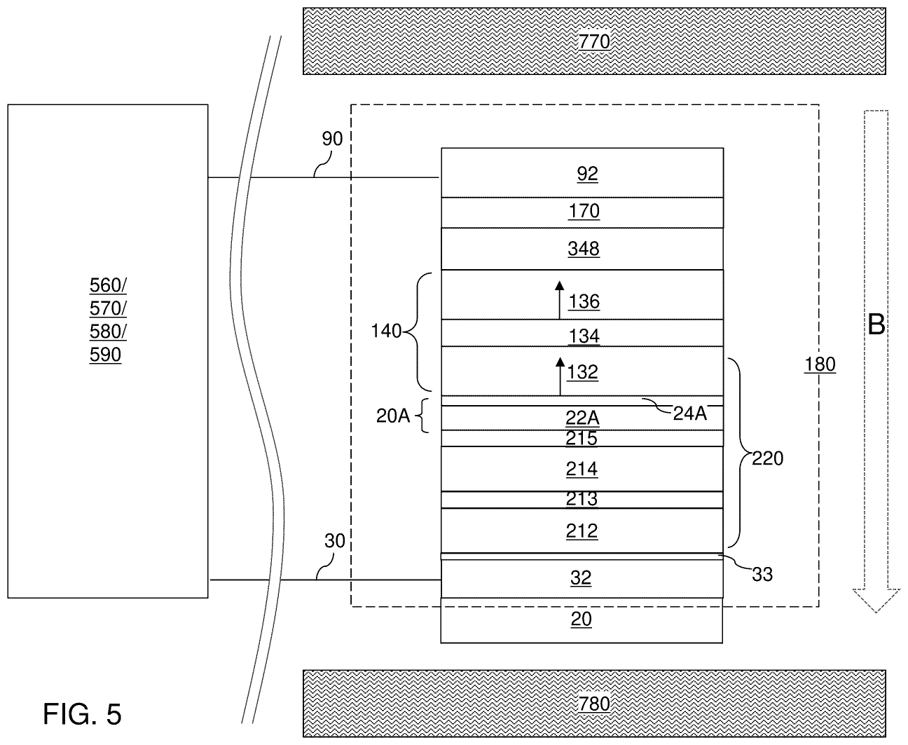

Referring to FIG. 5, a first configuration of an exemplary magnetoelectric device according to a first embodiment of the present disclosure is illustrated, which comprises a magnetoelectric unit cell 180. The magnetoelectric unit cell may be employed as a magnetoelectric unit cell 180 within the magnetoelectric device 500 illustrated in FIGS. 1-4B. According to the embodiment of the present disclosure, the magnetoelectric unit cell of the first embodiment of the present disclosure may be a voltage-controlled magnetic anisotropy (VCMA) magnetoelectric unit cell. The unit cell 180 can be formed on an insulating support 20 (which may include a silicon oxide layer), and can include a bottom electrode 32 that may be electrically connected to, or comprises, a portion of a first electrically conductive line 30 (such as a word line or a bit line) and a top electrode 92 that may be electrically connected to, or comprises, a portion of a second electrically conductive line 90 (such as a bit line or a word line).

A magnetic tunnel junction (MTJ) 140, a dielectric capping layer 348, and a nonmagnetic metallic capping layer 170 may be formed in a forward order or in a reverse order between the bottom electrode 32 and the top electrode 92. In one embodiment, a first reference layer 132 may be provided as a component within a first composite reference magnetization structure 220, which may include a composite superlattice SAF structure, which is described below in detail.

Optionally, a metallic seed layer 33 may be deposited directly on a top surface of the bottom electrode 32. The metallic seed layer 33 may include one or more of Ta, Ti, V, Cr, Mn, Zr, Nb, Mo, Pt, Ru, Rh, Hf, W, Re, Os, or Ir. In one embodiment, the metallic seed layer 33 can include tantalum and/or platinum. The metallic seed layer 33 can be deposited, for example, by sputtering. The metallic seed layer 33 can have a thickness in a range from 2 nm to 10 nm, although lesser and greater thicknesses may also be employed.

The magnetic tunnel junction 140 includes a first reference layer 132 (which may also be referred to as a “pinned” layer) having a fixed vertical magnetization, a nonmagnetic tunnel barrier layer 134, and the free layer 136 (which may also be referred to as a “storage” layer) having a magnetization direction that can be programmed. The first reference layer 132 and the free layer 136 can be separated by the nonmagnetic tunnel barrier layer 134 (such as an MgO layer), and have a magnetization direction perpendicular to the interface between the free layer 136 and the nonmagnetic tunnel barrier layer 134.

In one embodiment, the first reference layer 132 is located below the nonmagnetic tunnel barrier layer 134, while the free layer 136 is located above the nonmagnetic tunnel barrier layer 134. A dielectric capping layer 348 may be formed on top of the free layer 136. However, in other embodiments, the first reference layer 132 is located above the nonmagnetic tunnel barrier layer 134, while the free layer 136 is located below the nonmagnetic tunnel barrier layer 134, or the first reference layer 132 and the free layer 136 may be located on opposite sides of the nonmagnetic tunnel barrier layer 134. The free layer 136 may be programmed into a first magnetization (e.g., magnetization direction) that is parallel to the fixed vertical magnetization (e.g., magnetization direction) of the first reference layer 132, and a second magnetization (e.g., magnetization direction) that is antiparallel to the fixed vertical magnetization (e.g., magnetization direction) of the first reference layer 132.

The first reference layer 132 can include either a Co/Ni or Co/Pt multilayer structure or any other material that have larger perpendicular magnetic anisotropy than the free layer 136. In one embodiment, the first reference layer 132 can additionally include a thin non-magnetic layer comprised of tantalum or tungsten having a thickness in a range from 0.2 nm to 0.5 nm and a thin CoFeB layer (having a thickness in a range from 0.5 nm to 3 nm). The first reference layer 132 has a fixed magnetization direction that does not change during operation of the magnetoelectric unit cell 180. The fixed magnetization direction may be an upward direction or may be a downward direction.

The nonmagnetic tunnel barrier layer 134 can include any tunneling barrier material such as an electrically insulating material, for example magnesium oxide or a magnesium aluminum oxide spinel. In one embodiment, the nonmagnetic tunnel barrier layer 134 comprises, and/or consists essentially of, magnesium oxide and has a thickness in a range from 0.5 nm to 3 nm, such as from 1.8 nm to 2.5 nm.

The free layer 136 includes a ferromagnetic material such as CoFeB, CoFe, Co, Ni, NiFe, or a combination thereof. If a CoFeB alloy is included in the free layer 136, then the atomic concentration of boron atoms within the CoFeB alloy may be in a range from 10% to 30% (such as 20%), the atomic concentration of cobalt atoms within the CoFeB alloy may be in a range from 10% to 40% (such as 15%), and the atomic concentration of Fe in the CoFeB layer may be in a range from 50% to 90% (such as 65%). Any impurity atom in the CoFeB alloy, if present, has an atomic concentration less than 1 parts per million. The CoFeB alloy may be deposited in the amorphous state on a crystalline MgO nonmagnetic tunnel barrier layer 134 which has a rocksalt crystal structure. During a subsequent anneal of the device, the CoFeB alloy crystallizes into a body-centered cubic crystal structure using the MgO layer as a crystallization template, while some or all of the boron atoms diffuse away from the interface with the MgO layer. Thus, a proximal portion of the free layer 136 that contacts the nonmagnetic tunnel barrier layer 134 may comprise a CoFe alloy or a CoFeB alloy having a body-centered cubic crystal structure, and may provide a coherent interface with the nonmagnetic tunnel barrier layer 134, particularly with MgO and a higher TMR. The thickness of the free layer 136 can be in a range from 0.5 nm to 2 nm, although lesser and greater thicknesses can also be employed.

As used herein, a “thickness” of any deposited film having a thickness less than 10 nm is the product of the deposition time and the deposition rate as measured by deposition of a thicker film that can be physically measured by optical methods or by scanning electron microscopy. The deposition rate can be calibrated independently on thicker films for each material. A single monolayer of a material has an equivalent thickness of the monolayer of the material. A material that forms a fraction of a monolayer has an equivalent thickness of the fraction times the thickness of the monolayer of the material. If the fraction is less than one, then the material is a discontinuous layer in which the equivalent thickness can be less than the thickness of the monolayer of the material. As used herein, a “sub-monolayer” refers to a film having an average thickness less than one monolayer (e.g., less than 0.5 nm thick). In embodiments of the present disclosure, a sub-monolayer film can be a discontinuous layer having openings therethrough or can be a collection of individual atoms or clusters of atoms that do not form a continuous layer depending on the fractional number of an atomic layer that is present therein.

An interface between a magnetic film and a nonmagnetic film can be magnetoelectric, i.e., can exhibit a magnetic property that is sensitive to the electric field in the nonmagnetic film. When some dielectric materials are in contact with, or in close proximity with, a ferromagnetic material, may cause the ferromagnetic material to exhibit the voltage-controlled magnetic anisotropy (VCMA) effect within the ferromagnetic material. The VCMA effect refers to an effect in which the magnetic anisotropy of a ferromagnetic material depends on the electric field within a dielectric material in direct contact with, or in close proximity to, the ferromagnetic material. Generally, the VCMA effect is believed to be due to spin-dependent charge screening and electric field-induced modulation of the relative occupancy of d orbitals at an interface between a ferromagnetic material and a dielectric material.

In one embodiment, a dielectric capping layer 348 can be formed over the free layer 136. The dielectric capping layer 348 is a dielectric material layer that decreases the magnetic anisotropy in the free layer 136 when electric field is present therein along a direction perpendicular to an interface with the free layer 136. In one embodiment, the dielectric capping layer 348 has a dielectric constant of greater than 10, such as 25 or more, such as 25 to 80,000, for example 25 to 150, to enhance the VCMA effect in the magnetoelectric unit cell 180. The thickness of the dielectric capping layer 348 can be in a range from 0.5 nm to 10 nm, such as from 1 nm to 2 nm.

The dielectric capping layer 348 can be as thick or even thicker than the nonmagnetic tunnel barrier layer 134, and may have the same or a higher dielectric constant than the nonmagnetic tunnel barrier layer 134. This shifts the VCMA effect which controls the magnetization direction of the free layer from the interface between the free layer 136 and the nonmagnetic tunnel barrier layer 134 to the interface between the free layer 136 and the dielectric capping layer 348. Thus, the tunneling magnetoresistance (TMR) of the magnetoelectric unit cell 180 may be maintained because the interface between the free layer 136 and the nonmagnetic tunnel barrier layer 134 is not degraded, while the VCMA effect in enhanced due to the higher dielectric constant of the dielectric capping layer 348.

In one embodiment, the dielectric material of the dielectric capping layer 348 includes a dielectric material having a dielectric constant of 10 or greater, such as 25 or greater, when having a thickness of 10 nm or less, such as 1 nm to 5 nm. While many dielectric materials provide a dielectric constant greater than 10 in a bulk state, some dielectric materials have a lower or higher dielectric constant in a thin film having a thickness of 10 nm or less. In one embodiment, the dielectric material of the dielectric capping layer 348 can be selected such that the dielectric material has a dielectric constant of 10 or greater when the dielectric capping layer 348 a thickness of 10 nm or less, such as a thickness in range from 1 nm to 5 nm.

In one embodiment, the dielectric material of the dielectric capping layer 348 can include, and/or can consist essentially of at least one transition-metal-containing dielectric metal oxide material, such as magnesium oxide, hafnium oxide or a magnesium aluminum oxide spinel. In an alternative embodiment, the dielectric material of the dielectric capping layer 348 can comprise, and/or can consist essentially of, a material that has a dielectric constant of 25 and higher, such as strontium titanate, barium titanate, barium strontium titanate, lead zirconate titanate, lead lanthanum titanate, lead lanthanum titanate zirconate, lead lanthanum zirconate, bismuth ferrite or calcium copper titanate (which is reported to have a dielectric constant of about 80,000).

In one embodiment, the voltage drop across the dielectric capping layer 348 can be greater than the voltage drop across the nonmagnetic tunnel barrier layer 134 during programming, i.e., writing. Ignoring the effect of the nonmagnetic tunneling current, the ratio of the voltage drop across the dielectric capping layer 348 to the voltage drop across the nonmagnetic tunnel barrier layer 134 is approximately the same as the ratio of the thickness-to-dielectric constant ratio for the dielectric capping layer 348 to the thickness-to-dielectric constant ratio for the nonmagnetic tunnel barrier layer 134. A thickness-to-dielectric constant ratio refers to the ratio of the thickness of a dielectric layer to the dielectric constant of the dielectric layer. Thus, the thickness-to-dielectric constant ratio for the dielectric capping layer 348 can be greater than the thickness-to-dielectric constant ratio for the nonmagnetic tunnel barrier layer 134.

According to an embodiment of the present disclosure, the magnetic tunnel junction 140 may comprise, from a side of the bottom electrode 32 toward the top electrode 92, the first reference layer 132, the nonmagnetic tunnel barrier layer 134, the free layer 136, and the dielectric capping layer 348.

In one embodiment, each of the nonmagnetic tunnel barrier layer 134 and the dielectric capping layer 348 comprises, and/or consists essentially of, a respective material selected from magnesium oxide or magnesium aluminum oxide spinel material. In one embodiment, the thickness-to-dielectric constant ratio for the dielectric capping layer 348 can be greater than the thickness-to-dielectric constant ratio for the nonmagnetic tunnel barrier layer 134.

In one embodiment, a nonmagnetic metallic material can be provided on the side of the dielectric capping layer 348 that faces away from the free layer 136. For example, a nonmagnetic metallic capping layer 170 can be formed directly on the dielectric capping layer 348. The nonmagnetic metallic capping layer 170 includes at least one non-magnetic electrically conductive material such as tantalum, ruthenium, tantalum nitride, copper, and/or copper nitride. For example, the nonmagnetic metallic capping layer 170 can comprise a single layer, such as a single ruthenium layer, or a layer stack including, from one side to another, a first ruthenium layer, a tantalum layer, and a second ruthenium layer. For example, the first ruthenium layer can have a thickness in a range from 0.5 nm to 1.5 nm, the tantalum layer can have a thickness in a range from 1 nm to 3 nm, and the second ruthenium layer can have a thickness in a range from 0.5 nm to 1.5 nm. Optionally, the nonmagnetic metallic capping layer 170 may include an additional non-magnetic electrically conductive material, such as W, Ti, Ta, WN, TiN, TaN, Ru, and Cu. The thickness of such an additional non-magnetic electrically conductive material can be in a range from 1 nm to 30 nm, although lesser and greater thicknesses can also be employed.

In one embodiment, the top electrode 92 can be formed over the nonmagnetic metallic capping layer 170 as a portion of a second electrically conductive line 90. In this case, the nonmagnetic metallic capping layer 170 may contact the dielectric capping layer 348 and the top electrode 92.

In one embodiment, the composite reference magnetization structure 220 may include the first reference layer 132 and a fixed vertical magnetization structure (212, 213, 214). The fixed vertical magnetization structure may comprise a composite synthetic antiferromagnet (SAF) structure including a first superlattice 212, a second superlattice 214, and an antiferromagnetic coupling layer 213 having a thickness that provides antiferromagnetic coupling between the first superlattice 212 and the second superlattice 214. In one embodiment, the first superlattice comprises a first superlattice of first cobalt layers and first platinum layers, and the second superlattice 214 comprises a second superlattice of second cobalt layers and second platinum layers. In one embodiment, the first superlattice 212 comprises N1 repetitions of a first unit layer stack of a first cobalt layer and a first platinum layer, and a first capping cobalt layer such that N1 first platinum layers are interlaced with (N1+1) first cobalt layers. The integer N1 may be in a range from 2 to 10, such as from 3 to 6, although lesser and greater numbers may also be employed for N1. In one embodiment, the second superlattice 214 comprises N2 repetitions of a second unit layer stack of a second cobalt layer and a second platinum layer, and a second capping cobalt layer such that N2 first platinum layers are interlaced with (N2+1) second cobalt layers. The integer N2 may be in a range from 2 to 10, such as from 3 to 6, although lesser and greater numbers may also be employed for N2. In an illustrative example, the first cobalt layers and the second cobalt layers may have a respective thickness of 0.2 nm to 0.5 nm, and the first platinum layers and the second platinum layers may have a respective thickness of about 0.1 nm to 0.3 nm. It is understood that a material layer having a thickness that is less than the thickness of a monolayer refers to a discontinuous layer having a fractional coverage that is equal to the ratio of the thickness of the material layer to the thickness of the monolayer.

The antiferromagnetic coupling layer 213 comprises a material composition and a thickness that provide antiferromagnetic coupling between the first permanent ferromagnetic layer 212 and the second permanent ferromagnetic layer 214. In one embodiment, the antiferromagnetic coupling layer 213 can include ruthenium or iridium, and can have a thickness in a range from 0.3 nm to 0.8 nm.

In one embodiment, the composite reference magnetization structure 220 may also include a first nonmagnetic spacer metal layer 215, which may be optionally located on a planar top surface of the fixed vertical magnetization structure (212, 213, 214). The first nonmagnetic spacer metal layer 215 can comprise, and/or consist essentially of, at least one refractory metal having a melting point higher than 2,000 degrees Celsius. For example, the first nonmagnetic spacer metal layer 215 can comprise, and/or consist essentially of, at least one metal selected from W, Mo or Ta. The thickness of the first nonmagnetic spacer metal layer 215 may be in a range from 0.1 nm to 0.3 nm, such as from 0.15 nm to 0.25 nm, although lesser and greater thicknesses may also be employed. The first nonmagnetic spacer metal layer 215 may be deposited, for example, by physical vapor deposition. In one embodiment, the first nonmagnetic spacer metal layer 215 may consist essentially of tungsten.

In one embodiment, the composite reference magnetization structure 220 may also include an optional second reference layer stack 20A which may be located between the first nonmagnetic spacer metal layer 215 and the first reference layer 132. The second reference layer stack 20A comprises a second reference layer 22A including a respective ferromagnetic material having perpendicular magnetic anisotropy, and a spacer dielectric metal oxide layer 24A.

The layer stack including the first composite reference magnetization structure 220, the magnetic tunnel junction 140, the dielectric capping layer 348, and the nonmagnetic metallic capping layer 170 can be annealed to induce crystallographic alignment between the crystalline structure of the nonmagnetic tunnel barrier layer 134 (which may include crystalline MgO having a rock salt crystal structure) and the crystalline structure of the free layer 136.

The location of the bottom electrode 32 and the top electrode 92 may be switched such that the top electrode 92 is electrically connected to the first composite reference magnetization structure 220 and the bottom electrode 32 is electrically connected to the nonmagnetic metallic capping layer 170. The layer stack including the material layers from the first composite reference magnetization structure 220 to the nonmagnetic metallic capping layer 170 can be deposited in reverse order, i.e., from the first composite reference magnetization structure 220 toward the nonmagnetic metallic capping layer 170 or from the nonmagnetic metallic capping layer 170 toward the first composite reference magnetization structure 220. The layer stack can be formed as a stack of continuous layers, and can be subsequently patterned into discrete patterned layer stacks for each unit cell 180.

Optionally, each unit cell 180 can include a dedicated steering device, such an access transistor (not shown) or a diode configured to activate a respective discrete patterned layer stack (220, 140, 348, 170) upon application of a suitable voltage to the steering device. The steering device may be electrically connected between the patterned layer stack and one of the first electrically conductive lines 30 or one of the second electrically conductive lines 90.

The first reference layer 132 has a fixed vertical magnetization that is perpendicular to an interface between the first reference layer 132 and the nonmagnetic tunnel barrier layer 134. The free layer 136 has perpendicular magnetic anisotropy to provide bistable magnetization states that include a parallel state having a magnetization that is parallel to the fixed vertical magnetization and an antiparallel state having a magnetization that is antiparallel to the fixed vertical magnetization.

The unit cell 180 can be programmed employing the voltage-controlled magnetic anisotropy (VCMA) effect. Thus, the magnetoelectric unit cell 180 can be programmed employing an electrical voltage that is applied in one direction. In other words, a voltage is applied between a selected word line and a selected bit line, and the magnetoelectric unit cell 180 can be toggled back and forth between the parallel and anti-parallel states by pulsing a voltage in one direction (e.g., in forward bias mode). In one embodiment, a very small current may flow between the free layer 136 and the first reference layer 132 during the writing step. However, the current is typically so small that spin-transfer torque (STT) effects can be ignored, and Ohmic dissipation should be minimal which reduces the write power. Optionally, an in-plane ancillary magnetic field may be provided by an external field source 60 configured to apply an in-plane ancillary magnetic field to the free layer 136.

A control circuit (560, 570, 580, 590) provides a unipolar voltage between the bottom electrode 32 and the top electrode 92. The control circuit (560, 570, 580, 590) may the same as described above. The control circuit (560, 570, 580, 590) can have two nodes that are connected to a respective one of the bottom electrode 32 and the top electrode 92 via a respective first electrically conductive line 30 and a respective second electrically conductive line 90.

Generally, the control circuit (560, 570, 580, 590) can be configured to perform a programming operation by applying a programming pulse to a selected VCMA magnetoelectric unit cell 180 within the VCMA magnetoelectric device. The programming pulse has a same polarity (i.e., the first polarity) for a first magnetization state (i.e., a parallel alignment state) in which a free layer 136 and a first reference layer 132 in the selected VCMA magnetoelectric unit cell have parallel magnetization directions, and for a second magnetization state (i.e., an antiparallel alignment state) in which the free layer 136 and the first reference layer 132 in the selected VCMA magnetoelectric unit cell have antiparallel magnetization directions. The control circuit (560, 570, 580, 590) can be configured to select a target VCMA magnetoelectric unit cell to be programmed within the VCMA magnetoelectric device, to determine an alignment state of magnetization of a free layer 136 (e.g., by reading the unit cell) and to apply a programming pulse if the alignment state of the target VCMA magnetoelectric unit cell is opposite to a target alignment configuration for the target VCMA magnetoelectric unit cell (thus, necessitating flipping of the magnetization of the free layer 136), and not to apply any programming pulse if the alignment state of the target VCMA magnetoelectric unit cell is in the target alignment configuration for the target VCMA magnetoelectric unit cell.

The programming pulse generates an electric field in the VCMA capping dielectric layer 348 and induces precession of a magnetization of a free layer 136 around an axis determined by magnetostatic interactions of various magnetic layers and the external magnetic field. In one embodiment, the programming pulse can be terminated when the polar angle is within a range from 0 radian to π/20 or when the polar angle is within a range from 19π/20 to π.

In one embodiment, an optional external field source 60 can be provided, which is configured to apply an in-plane ancillary magnetic field to the free layer 136. The in-plane ancillary magnetic field induces gyration of an azimuthal magnetization direction of the free layer 136 upon application of an electric field between the bottom electrode 32 and the top electrode 92.

In one embodiment, the control circuit (560, 570, 580, 590) may be configured to perform a sensing operation that determines a magnetization state of the free layer 136 by applying a sense voltage across the top electrode 92 and the bottom electrode 32 and by measuring magnetoresistance of the magnetic tunnel junction 140; to perform a comparison operation that determines whether the magnetization state of the free layer 136 is at a target magnetization state selected from an upward-pointing magnetization state and a downward-pointing magnetization state; and to apply a programming pulse across the top electrode 92 and the bottom electrode 32 only if the magnetization state of the free layer 136 is not the target magnetization state, and not to apply the programming pulse if the magnetization state of the free layer 136 is the target magnetization state.

In one embodiment, the programming pulse has a same polarity for programming the upward-pointing magnetization state into the downward-pointing magnetization state and for programming the downward-pointing magnetization state into the upward-pointing magnetization state.

In one embodiment, the sense voltage has a first polarity and generates a first electric field within the free layer 136 along a direction that increases magnetic anisotropy of the free layer 136; and the programming pulse has a second polarity that is an opposite of the first polarity and generates a second electric field within the free layer 136 along a direction that decreases magnetic anisotropy of the free layer 136. In one embodiment, the polarity of the sensing voltage is selected such that the applied electric field during the sensing operation increases the magnetic anisotropy of the free layer 136 through the VCMA effect (and thus, flipping of the magnetization of the free layer 136 becomes more difficult due to the applied field), and the polarity of the programming voltage is selected such that applied electric field during the programming operation decreases the magnetic anisotropy of the free layer 136 through the VCMA effect (and thus, flipping of the magnetization of the free layer 136 becomes easier due to the applied field).

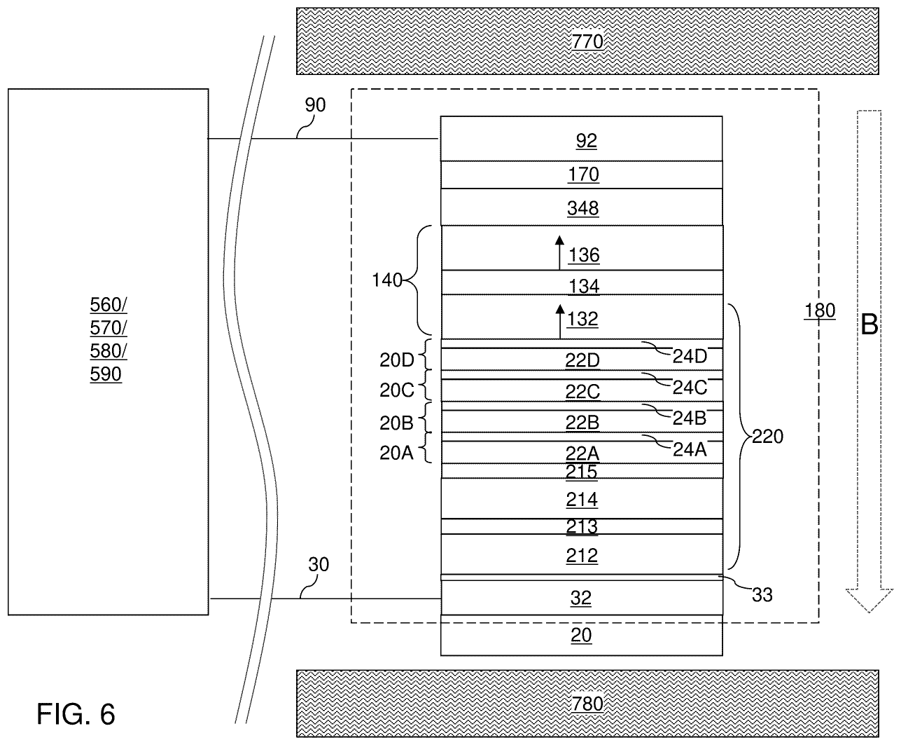

Referring to FIG. 6, a second configuration of exemplary magnetoresistive device can be derived from the first configuration of exemplary magnetoresistive device by modifying the first composite reference magnetization structure 220. The first composite reference magnetization structure 220 is located between the bottom electrode 32 and the nonmagnetic tunnel barrier layer 134. The first composite reference magnetization structure 220 can include, along a direction from the bottom electrode 32 toward the top electrode 92, a fixed vertical magnetization structure (212, 213, 214) configured to generate a fixed vertical magnetic field at a planar end surface, a first nonmagnetic spacer metal layer 215, and the first reference layer 132. At least one first layer stack (20A, 20B, 20C, 20D) may be located between the first nonmagnetic spacer metal layer 215 and the first reference layer 132. The at least one first layer stack (20A, 20B, 20C, 20D) comprises a respective additional reference layer (22A, 22B, 22C, 22D) including a respective ferromagnetic material having perpendicular magnetic anisotropy, and a respective spacer dielectric metal oxide layer, such as a spacer dielectric metal oxide layer (24A, 24B, 24C, 24D).

In one embodiment, each of at least one additional reference layer (22A, 22B, 22C, 22D) comprises, and/or consists essentially of, a material selected from CoFe and/or CoFeB. In one embodiment, each of the at least one additional reference layer (22A, 22B, 22C, 22D) comprises, and/or consists essentially of, CoFeB. In another embodiment, the additional reference layers (22A, 22B, 22C, 22D) comprise a first subset of the additional reference layers (e.g., 22A, 22B) that are located proximal to the fixed vertical magnetization structure (212, 213, 214) (including a bottommost additional reference layer 22A) and that comprise, and/or can consist essentially of, CoFe, and a second subset of the additional reference layer (e.g., 22C, 22D) that are located proximal to the magnetic tunnel junction 140 (including a topmost additional reference layer 22D) and that comprise, and/or can consist essentially of, CoFeB. Each of at least one additional reference layers (22A, 22B, 22C, 22D) can be deposited, for example, by physical vapor deposition. Each of the at least one additional reference layer (22A, 22B, 22C, 22D) can be have a thickness in a range from 0.2 nm to 0.6 nm, such as from 0.3 nm to 0.5 nm, although lesser and greater thicknesses may also be employed.

The spacer dielectric metal oxide layer (24A, 24B, 24C, 24D) comprises, and/or consists essentially of, a material selected from magnesium oxide, hafnium oxide, tantalum oxide, or aluminum oxide. In one embodiment, the at least one spacer dielectric metal oxide layer (24A, 24B, 24C, 24D) comprises, and/or consists essentially of, magnesium oxide.

In another embodiment, the spacer dielectric metal oxide layers (24A, 24B, 24C, 24D) comprise a first subset of spacer dielectric metal oxide layers (e.g., 24A, 24B) that are located proximal to the fixed vertical magnetization structure (212, 213, 214) (including a bottommost spacer dielectric metal oxide layer 24A) and that comprise, and/or can consist essentially of, a dielectric metal oxide other than magnesium oxide, such as hafnium oxide, tantalum oxide, or aluminum oxide, and a second subset of the dielectric metal oxide layers (e.g., 24C, 24D) that are located proximal to the magnetic tunnel junction 140 (including a topmost dielectric metal oxide layer 24D) and that comprise, and/or can consist essentially of, magnesium oxide.

Each of the spacer dielectric metal oxide layers (24A, 24B, 24C, 24D) may be formed by a respective physical vapor deposition process, an atomic layer deposition process, or a chemical vapor deposition process. In one embodiment, each of the spacer dielectric metal oxide layers (24A, 24B, 24C, 24D) may have a smaller thickness than the nonmagnetic tunnel barrier layer 134. For example, each of the spacer dielectric metal oxide layers (24A, 24B, 24C, 24D) may have a thickness in a range from 0.2 nm to 0.8 nm and/or from 0.3 nm to 0.6 nm. The thickness of each of the spacer dielectric metal oxide layer (24A, 24B, 24C, 24D) may be in less than, equal to, or greater than the thickness of a monolayer of the material of the respective spacer dielectric metal oxide layer (24A, 24B, 24C, 24D).

In one embodiment, a topmost one of the at least one spacer dielectric metal oxide layers (24A, 24B, 24C, 24D) may be in contact with the reference layer 132. In an alternative embodiment, an additional nonmagnetic spacer metal layer may be located between the topmost one of the at least one spacer dielectric metal oxide layers (24A, 24B, 24C, 24D) and the reference layer 132. The additional nonmagnetic spacer metal layer can comprise, and/or consist essentially of, at least one metal selected from W, Mo or Ta. The thickness of the additional nonmagnetic spacer metal layer may be in a range from 0.2 nm to 0.8 nm, such as from 0.4 nm to 0.6 nm, although lesser and greater thicknesses may also be employed.

In one embodiment, at least one of the at least one spacer dielectric metal oxide layers (24A, 24B, 24C, 24D) comprises a respective first ferromagnetic-dielectric interface at a first planar surface that contacts one additional reference layers (22A, 22B, 22C, 22D), and a respective second ferromagnetic-dielectric interface at a second planar surface that contacts the reference layer 132 or another additional reference layer (22A, 22B, 22C, 22D). A third ferromagnetic-dielectric interface is located between the reference layer 132 and the nonmagnetic tunnel barrier layer 134. Thus, at least three ferromagnetic-dielectric interfaces are located between the nonmagnetic tunnel barrier layer 134 and the composite SAF structure (212, 213, 214) in the first composite reference magnetization structure 220.

The magnetic tunnel junction 140 can be located between the at least one first layer stack (20A, 20B, 20C, 20D) and the top electrode 92. Generally, the magnetic tunnel junction 140 comprises the reference layer 132, the free layer 136, and the nonmagnetic tunnel barrier layer 134 located between the reference layer 132 and the free layer 136. The reference layer 132 can be more proximal to the at least one first layer stack (20A, 20B, 20C, 20D) than the free layer 136 is to the at least one first layer stack (20A, 20B, 20C, 20D). In one embodiment, the nonmagnetic tunnel barrier layer 134 comprises, and/or consists essentially of, a material selected from magnesium oxide and a spinel material.

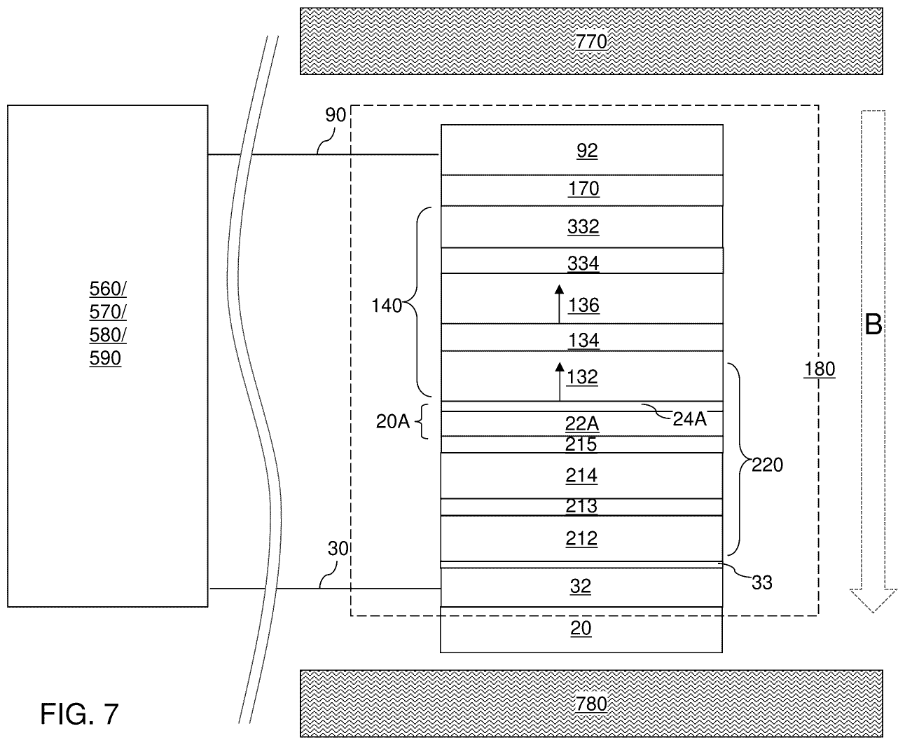

Referring to FIG. 7, a third configuration of exemplary magnetoresistive device may be derived from the first configuration or the second configuration of exemplary magnetoresistive device illustrated in FIG. 2 by inserting a second reference layer 332 between the dielectric capping layer 334 and the nonmagnetic metallic capping layer 170. The second reference layer 332 can be in contact with the dielectric capping layer 334, and can have the same magnetization direction as the first reference layer 132. In one embodiment, the second reference layer 332 can include any ferromagnetic material that may be employed for the first reference layer 132, and can have a thickness within the thickness range for the first reference layer 132. The second reference layer 332, if present, reinforces the reference magnetic field generated by the first reference layer 132.

In an alternative embodiment of the third configuration of exemplary magnetoresistive device, the second reference layer 332 is configured to provide a magnetic field that is substantially perpendicular to the magnetization axis of the free layer 136. As such, the second reference layer 332 is capable of providing an in-plane field around which the magnetization of the free layer 136 can precess during the writing process.

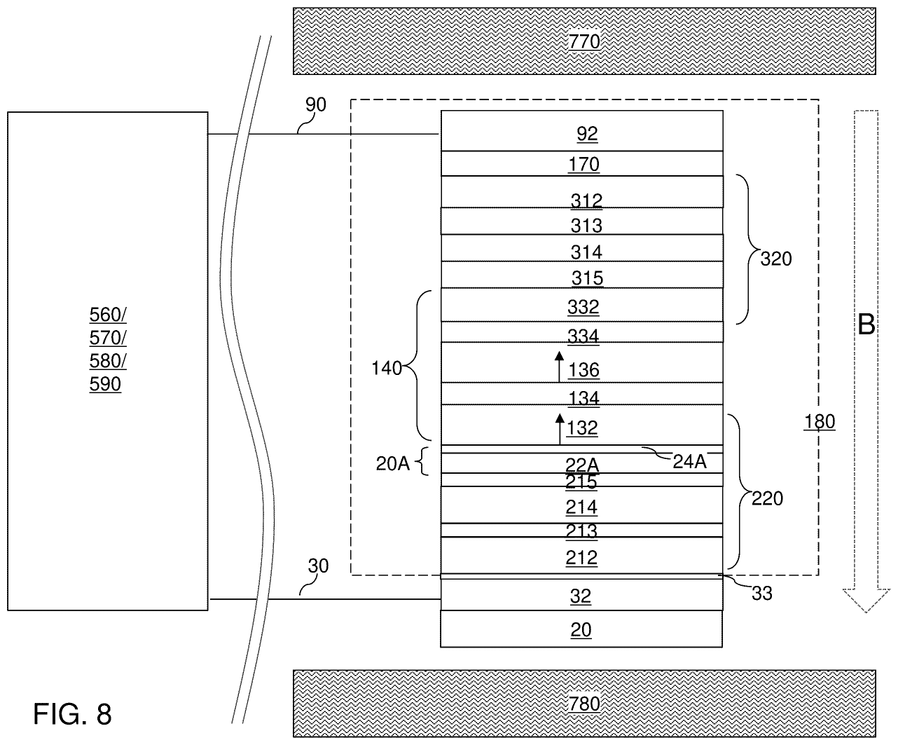

Referring to FIG. 8, a fourth configuration of exemplary magnetoresistive device may be derived from the third configuration of exemplary magnetoresistive device by providing a second composite reference magnetization structure 320 between the dielectric capping layer 334 and the top electrode 92. The second composite reference magnetization structure 320 includes, along a direction from the dielectric capping layer 334 toward the top electrode 92, the second reference layer 332, a second nonmagnetic spacer metal layer 315, and a fixed vertical magnetization structure (314, 313, 312) configured to generate a fixed vertical magnetic field at an interface with the second nonmagnetic spacer metal layer 315. In other words, the second composite reference magnetization structure 320 can include, along a direction from the top electrode 92 toward the free layer 136, a fixed vertical magnetization structure (312, 313, 314) configured to generate a fixed vertical magnetic field at a planar end surface and a second nonmagnetic spacer metal layer 315.

In one embodiment, the fixed vertical magnetization structure (312, 313, 314) may comprise a composite synthetic antiferromagnet (SAF) structure including a first superlattice 312, a second superlattice 314, and an antiferromagnetic coupling layer 313 having a thickness that provides antiferromagnetic coupling between the first superlattice 312 and the second superlattice 314. In one embodiment, the first superlattice comprises a first superlattice of first cobalt layers and first platinum layers, and the second superlattice 314 comprises a second superlattice of second cobalt layers and second platinum layers. In one embodiment, the first superlattice 312 comprises N1 repetitions of a first unit layer stack of a first cobalt layer and a first platinum layer, and a first capping cobalt layer such that N1 first platinum layers are interlaced with (N1+1) first cobalt layers. The integer N1 may be in a range from 2 to 10, such as from 3 to 6, although lesser and greater numbers may also be employed for N1. In one embodiment, the second superlattice 314 comprises N2 repetitions of a second unit layer stack of a second cobalt layer and a second platinum layer, and a second capping cobalt layer such that N2 first platinum layers are interlaced with (N2+1) second cobalt layers. The integer N2 may be in a range from 2 to 10, such as from 3 to 6, although lesser and greater numbers may also be employed for N2. In an illustrative example, the first cobalt layers and the second cobalt layers may have a respective thickness of 0.2 nm to 0.5 nm, and the first platinum layers and the second platinum layers may have a respective thickness of about 0.1 nm to 0.3 nm. It is understood that a material layer having a thickness that is less than the thickness of a monolayer refers to a discontinuous layer having a fractional coverage that is equal to the ratio of the thickness of the material layer to the thickness of the monolayer.

The antiferromagnetic coupling layer 313 comprises a material composition and a thickness that provide antiferromagnetic coupling between the first permanent ferromagnetic layer 312 and the second permanent ferromagnetic layer 314. In one embodiment, the antiferromagnetic coupling layer 313 can include ruthenium or iridium, and can have a thickness in a range from 0.3 nm to 0.8 nm.

The second nonmagnetic spacer metal layer 315 can be located on a planar bottom surface of the fixed vertical magnetization structure (312, 313, 314). The second nonmagnetic spacer metal layer 315 can comprise, and/or consist essentially of, at least one refractory metal having a melting point higher than 2,000 degrees Celsius. For example, the second nonmagnetic spacer metal layer 315 can comprise, and/or consist essentially of, at least one metal selected from W, Mo or Ta. The thickness of the second nonmagnetic spacer metal layer 315 may be in a range from 0.1 nm to 0.3 nm, such as from 0.15 nm to 0.25 nm, although lesser and greater thicknesses may also be employed. The second nonmagnetic spacer metal layer 315 may be deposited, for example, by physical vapor deposition. In one embodiment, the second nonmagnetic spacer metal layer 315 may consist essentially of tungsten.

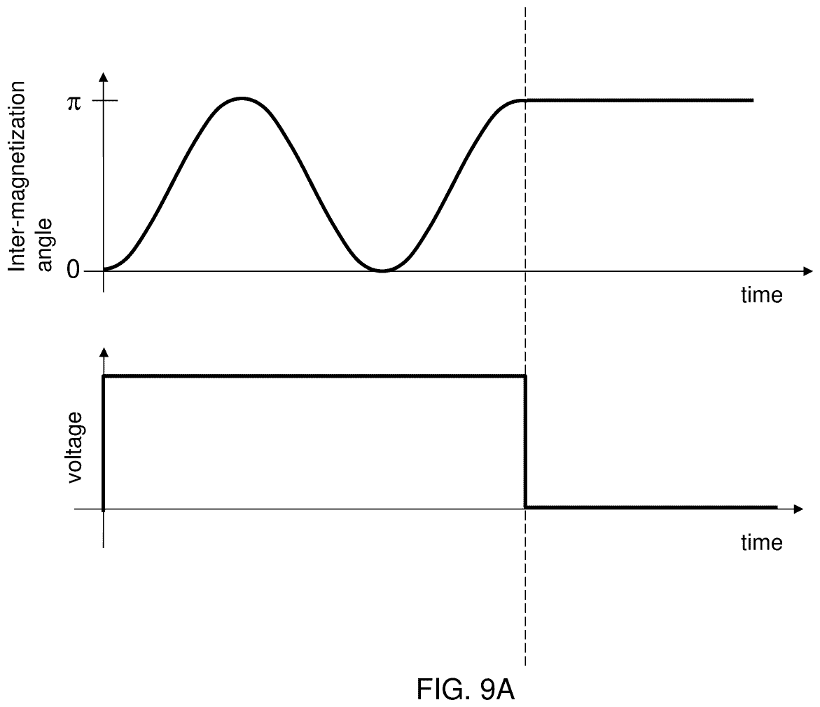

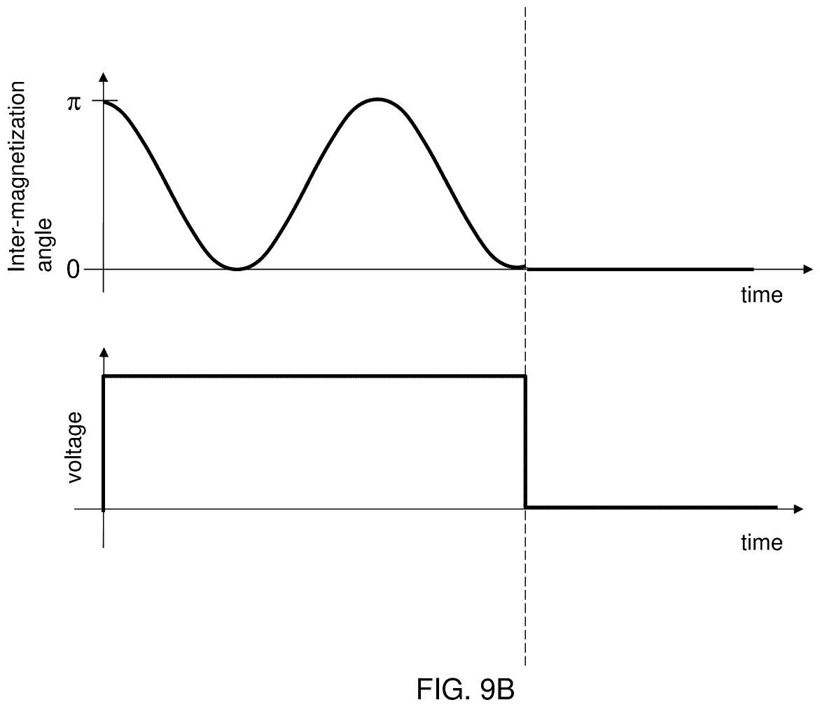

Referring to FIG. 9A, an example of a programming step is illustrated, in which a selected VCMA magnetoelectric unit cell 180 in a parallel alignment state is programmed into an antiparallel alignment state by a programming pulse of the first polarity that terminates when the polar angle between the magnetization direction of the free layer 136 with respect to the fixed magnetization direction of the first reference layer 132 is within a range from 19π/20 to π. The duration of the programming pulse may be in range from 0.02 ns to 0.5 ns, although lesser and greater duration of the programming pulse can also be employed.

Referring to FIG. 9B, an example of a programming step is illustrated, in which a selected VCMA magnetoelectric unit cell in an antiparallel alignment state is programmed into a parallel alignment state by a programming pulse of the first polarity that terminates when the polar angle between the magnetization direction of the free layer 136 with respect to the fixed magnetization direction of the first reference layer 132 is within a range from 0 to π/20.

Thus, the control circuit (560, 570, 580, 590) is configured to perform a programming operation by applying a programming voltage between the bottom electrode 32 and the top electrode 92, wherein the programming voltage has a same polarity for a first magnetization state in which the free layer 136 and the first reference layer 132 have parallel magnetization directions and for a second magnetization state in which the free layer and the reference layer have antiparallel magnetization directions. The magnitude of the programming voltage may be in a range from 500 mV to 3 V. The control circuit (560, 570, 580, 590) is also configured to perform a sensing (i.e., reading) operation by applying a voltage between 100 mV and 1.5 V between the first and second electrodes.

A method of operating the magnetoelectric unit cell 180 of the first embodiment comprises applying a first programming voltage of a first polarity between the bottom electrode 32 and the top electrode 92 to switch a first magnetization state of the free layer 136 in which the free layer and the first reference layer 132 have parallel magnetization directions to a second magnetization state of the free layer in which the free layer and the reference layer have antiparallel magnetization directions. The method further comprises applying a second programming voltage of the first polarity between the first electrode and the second electrode to switch the second magnetization state of the free layer to the first magnetization state of the free layer. The first programming voltage and the second programming voltage generate an electric field in the dielectric capping layer which induces precession in the free layer 136. As shown in FIGS. 9A and 9B, the method includes terminating the first programming voltage when the free layer has the first magnetization direction, and terminating the second programming voltage when the free layer has the second magnetization direction. In one embodiment, an external magnetic field is optionally applied by the external field source 60 during the step of applying the first programming voltage.

In another embodiment, the magnetoelectric unit cell 180 is programmed using programming voltages that reduce the magnetic anisotropy of the target unit cells 180 (i.e., the unit cells which are to be programmed). In one embodiment, the target unit cells 180 are arranged in a crosspoint configuration with no access devices, such as transistors. The applied voltages to the target bit line (90 or 30) and target word line (30 or 90) which are electrically connected to the target unit cells 180 are configured to greatly reduce the magnetic anisotropy of the target unit cells 180. For example, the target word line (30 or 90) is set to 2V, while the target bit line (90 or 30) is set to 0V, while the non-target word lines and non-target bit lines are set to 1V. In this embodiment the applied voltage is 2V on the target unit cell (i.e., data bit), 1V on the non-target unit cells (i.e., data bits) 180 that share a bit line or word line with the target unit cell (i.e., data bit) 180, and 0V on the non-target unit cells that do not share a bit line or word line with the target unit cell. The magnetic anisotropies of unit cells that share a bit line or word line with the target unit cell are reduced, but not as much as the target unit cell.

In an alternative embodiment, the target word line is set to 2V, the target bit line to 0V, the non-target word lines are set to 0V, and the non-target bit lines are set to 2V. In this embodiment the applied voltage is 2V on the target unit cell, 0V on the non-target unit cells that share a bit line or word line with the target unit cell, and −2V on the non-target unit cells that do not share a bit line or word line with the target unit cell. In this embodiment, the magnetic anisotropies of the non-target unit cells that share a bit line or word line with the target unit cell are not altered, making them less susceptible to being written inadvertently. Furthermore, the magnetic anisotropies of the unit cells that do not share a word line or a bit line with the target unit cell are enhanced, making them even less susceptible to having their magnetization state disturbed in the presence of a magnetic field. The exemplary voltage values described above are representative, and may be varied based on the device characteristics.

In a further embodiment, the embedded electromagnetic field generator 700 is used in conjunction with the applied write voltages to set the magnetization direction of the target unit cells so that the magnetization direction matches the easy-axis component of the field generated by the embedded electromagnet. In this embodiment, a process for programming (i.e., writing) the unit cells 180 of the computation array 550 to the desired configuration of magnetization states includes setting the magnetic field generator 720 to a first magnetic field direction, applying a set of write (i.e., programming) voltages to lower the magnetic anisotropy of a first target unit cell 180 in the computation array 550 so that it will switch in the applied magnetic field without adversely disturbing the magnetic configurations of the non-target unit cells 180, then applying successive sequences of write voltages to write all of the unit cells 180 in the computation array 520 whose desired magnetization matches the first magnetic field direction set by the magnetic field generator 720, then switching the generator 720 to a second magnetic field direction, and repeating the write procedure for the unit cells 180 whose desired magnetic configuration matches the second magnetic field direction, and then turning off the magnetic field.

The magnetoelectric device illustrated in FIGS. 2-8 can be manufactured by forming a layer stack including, from one side to another, a bottom electrode 32, a first reference layer 132, a nonmagnetic tunnel barrier layer 134, a free layer 136, a dielectric capping layer 348, and a top electrode 92 in a forward order or in a reverse order. A first composite reference magnetization structure 220 and/or a second composite reference magnetization structure 320 may optionally be employed. A control circuit (560, 570, 580, 590) can be formed, and the bottom electrode 32 and the top electrode 92 can be connected to a respective node of the control circuit (560, 570, 580, 590). The first reference layer 132 has a fixed magnetization direction, and the free layer 136 has magnetic anisotropy that provides magnetization directions that are parallel or antiparallel to the fixed magnetization direction.

Embodiments of the present disclosure provide an on-chip electromagnet that enhances vector-matrix multiplication (VMM) using voltage-controlled-magnetic-anisotropy (VCMA) MRAM cells. Devices of the embodiments of the present disclosure can reduce energy consumption and improve scalability, which are major problems encountered in traditional AI calculations. The device also eliminates the need for an external (i.e., off-chip) magnet for providing the magnetic field during programming operations.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A magnetoelectric device, comprising:
an array of magnetoelectric unit cells located over a substrate, wherein each of the magnetoelectric unit cells comprises a first electrode, a second electrode, and a magnetic tunnel junction located between the first electrode and the second electrode;
word lines contacting a respective row of first electrodes of the array of magnetoelectric unit cells;
bit lines contacting a respective column of second electrodes of the array of magnetoelectric unit cells; and
an electromagnet located over the substrate and configured to apply a magnetic field to the array of magnetoelectric unit cells.

2. The magnetoelectric device of claim 1, wherein the electromagnet comprises at least one conductive line, and the magnetoelectric unit cells comprise voltage-controlled magnetic anisotropy magnetoelectric unit cells.

3. The magnetoelectric device of claim 2, further comprising:
a magnetic field generation plate overlying the array of magnetoelectric unit cells; and
a current driver circuit configured to flow electric current through the at least one conductive line.

4. The magnetoelectric device of claim 3, wherein the at least one conductive line laterally extends around a respective sidewall of the magnetic field generation plate.

5. The magnetoelectric device of claim 4, wherein:
the at least one conductive line comprises a plurality of conductive lines laterally extending along different directions; and
the current driver circuit is configured to flow the electric current through each of the plurality of conductive lines along a respective electric current direction such that each of the electric current directions flows clockwise in a top-down view, or each of the electric current directions flows counterclockwise in the top-down view.

6. The magnetoelectric device of claim 5, wherein:
the magnetic field generation plate has a pair of first straight sidewalls that laterally extend along a first horizontal direction and a pair of second straight sidewalls that laterally extend along a second horizontal direction;
the plurality of conductive lines comprise a pair of first conductive lines that laterally extend along the first horizontal direction and a pair of second conductive lines that laterally extend along the second horizontal direction; and
the current driver circuit is configured to flow electric current through the pair of first conductive lines in opposite directions, and is configured to flow electric current through the pair of second conductive lines in opposite directions.

7. The magnetoelectric device of claim 5, wherein the pair second conductive lines is vertically offset relative to the pair of first conductive lines.

8. The magnetoelectric device of claim 5, wherein the plurality of conductive lines are not in direct contact with each other.

9. The magnetoelectric device of claim 5, wherein each of the plurality of conductive lines is laterally offset from a respective sidewall of the magnetic field generation plate by a respective uniform spacing.

10. The magnetoelectric device of claim 5, wherein:
the current driver circuit, a word line driver circuit, a bit line driver circuit, and a sense amplifier circuit are located over the substrate; and
the array of magnetoelectric unit cells is located over the current driver circuit.

11. The magnetoelectric device of claim 10, wherein each of the plurality of conductive lines comprises:
a respective first end portion that is electrically connected to a respective first interconnect structure that provides an electrical connection to a respective first node of the current driver circuit; and
a respective second end portion that is electrically connected to a respective second interconnect structure that provides an electrical connection to a respective second node of the current driver circuit.

12. The magnetoelectric device of claim 2, wherein:
a topmost surface of the at least one conductive line is located below a first horizontal plane including a top surface of the magnetic field generation plate; and
a bottommost surface of the at least one conductive line is located above a second horizontal plane including a bottom surface of the magnetic field generation plate.

13. The magnetoelectric device of claim 2, further comprising:
an additional array of magnetoelectric unit cells;
additional word lines contacting a respective row of first electrodes of the additional array of magnetoelectric unit cells;
additional bit lines contacting a respective column of second electrodes of the additional array of magnetoelectric unit cells; and
an additional magnetic field generation plate overlying the additional array of magnetoelectric unit cells,
wherein the at least one conductive line is located between the magnetic field generation plate and the additional magnetic field generation plate and is configured to generate an upward-pointing magnetic field in one of the magnetic field generation plate and the additional magnetic field generation plate, and to generate a downward-pointing magnetic field in another of the magnetic field generation plate and the additional magnetic field generation plate.

14. The magnetoelectric device of claim 1, wherein the magnetic field generation plate overlies the word lines, the array of magnetoelectric unit cells, and the bit lines.

15. The magnetoelectric device of claim 14, further comprising a soft magnetic material plate that underlies the word lines, the array of magnetoelectric unit cells, and the bit lines.

16. The magnetoelectric device of claim 15, wherein:
the soft magnetic material plate has an areal overlap within an entirety of the array of magnetoelectric unit cells; and
the magnetic field generation plate covers an entire area of the array of magnetoelectric unit cells.

17. The magnetoelectric device of claim 1, wherein that array of magnetoelectric unit cells and the electromagnet are located in a same chip or die.

18. The magnetoelectric device of claim 1, wherein:
each of the magnetoelectric unit cells comprises a voltage-controlled magnetic anisotropy unit cell; and
the magnetic tunnel junction comprises a ferromagnetic free layer, a ferromagnetic reference layer, and a tunnel barrier layer located between the ferromagnetic free layer and the ferromagnetic reference layer.

19. The magnetoelectric device of claim 18, further comprising a word line driver circuit and a bit line driver circuit that are located over the substrate, and are configured to provide a unipolar voltage pulse across a selected magnetoelectric unit cell within the array of magnetoelectric unit cells, wherein the unipolar voltage pulse induces precession of a magnetization direction in the ferromagnetic free layer of the selective magnetoelectric unit cell while a vertical magnetic field is present within the array of magnetoelectric unit cells and in the magnetic field generation plate.

20. A method of operating the magnetoelectric device of claim 18, comprising performing a vector-matrix multiplication calculation using the array of magnetoelectric unit cells.
